(19) United States
(12) Patent Application Publication
(10) Pub. No.: US 2014/0130871 A1
(43) Pub. Date: May 15, 2014

(54) PHOTOELECTRIC CONVERSION ELEMENT AND MANUFACTURING METHOD THEREOF

(71) Applicant: ASAHI GLASS COMPANY, LIMITED, Tokyo (JP)

(72) Inventors: Shinya TAHARA, Tokyo (JP); Yuriko KAIDA, Tokyo (JP); Takashi SASAKI, Tokyo (JP); Yuichiro OGATA, Tokyo (JP)

(73) Assignee: ASAHI GLASS COMPANY, LIMITED, Tokyo (JP)

(21) Appl. No.: 14/157,376

(22) Filed: Jan. 16, 2014

Related U.S. Application Data
(63) Continuation of application No. PCT/JP2012/069156, filed on Jul. 27, 2012.

(30) Foreign Application Priority Data
Jul. 28, 2011 (JP) 2011-165417

(51) Int. Cl. H01L 51/00

(52) U.S. Cl. CPC H01L 51/0076; H01L 51/0034; H01L 51/0046
USPC 136/263; 438/82

(57) ABSTRACT

There are provided a photoelectric conversion element with high photoelectric conversion efficiency, whose light absorption efficiency, charge separation efficiency, and charge transport efficiency are at high level, and a method for efficiently manufacturing the photoelectric conversion element. A photoelectric conversion element has an anode, a cathode opposed to the anode, and an organic film disposed between the anode and the cathode and containing a liquid-crystalline conjugated block polymer. A method of manufacturing the above mentioned photoelectric conversion element has the step of, (1) preparing an organic film forming composition containing the liquid-crystalline conjugated block polymer; (2) forming the one electrode and a coating film using the composition on it; (3) heat treating the coating film within a temperature range in a liquid-crystalline state so as to obtain an organic film; and (4) forming the other electrode which is not formed in the step (2) above the organic film.

### CROSS-REFERENCE TO RELATED APPLICATIONS

This application is a continuation of prior International Application No. PCT/JP2012/069156, filed on Jul. 27, 2012 which is based upon and claims the benefit of priority from Japanese Patent Application No. 2011-165417 filed on Jul. 28, 2011; the entire contents of all of which are incorporated herein by reference.

### TECHNICAL FIELD

The present invention relates to a photoelectric conversion element using an organic film and a manufacturing method thereof.

### BACKGROUND ART

As a solar cell which is one of photoelectric conversion elements, a solar cell using an organic thin film is being developed. Photoelectric conversion in the organic thin film takes place in a thin film combining an electron donor phase and an electron acceptor phase sandwiched between a cathode and an anode. Specifically, an exciton which occurred in the electron donor phase by light absorption moves to an interface between the electron donor phase and the electron acceptor phase, and charge separated into a hole and an electron. After charge separated, the electron moves to the cathode through the electron acceptor phase and the hole moves to the anode through the electron donor phase. That is, charge transport is performed to generate electric power.

For increasing photoelectric conversion efficiency in the photoelectric conversion element using the organic thin film, it is necessary to increase light absorption efficiency, and further to perform the charge separation and the charge transport efficiently. In order to increase the light absorption efficiency, it is required to ensure that the organic thin film has a film thickness of a desired thickness of, specifically, 100-nm order. In order to increase charge separation efficiency, it is necessary to efficiently cause excitons, whose movable distance is 10 nm, to come in contact with the interface between the electron donor phase and the electron acceptor phase, and hence it is required to secure a sufficiently large area of this interface. Further, in order to increase charge transport efficiency, there is demanded a structure which secures the above-described two required characteristics, and moreover the electron donor phase and the electron acceptor phase each exist in continuation to the anode and the cathode.

Accordingly, development being conducted for satisfying these required characteristics in the photoelectric conversion element using the organic thin film. For example, Patent Reference 1 (US Patent Application Publication No. 2004/0099307) describes a technology of an organic thin film using a block copolymer having an electron-donating block and an electron-accepting block which are both π-conjugated. In Patent Reference 1, a structure is obtained in which electron donor phases and electron acceptor phases are arrayed alternately and perpendicularly between electrodes by using a second-order structure and a third-order structure in which the block copolymer is self-organized and layered. Here, as means for causing self-organization of the block copolymer, Patent Reference 1 exemplifies a magnetic field, an electric field, or a polarized light, and the like. However, by the disclosed method, it is practically impossible to construct such a structure with a film thickness which sufficiently ensures absorption of light.

Further, Patent Reference 2(Japanese Patent Application Laid-open No. 2008-115286) describes a technology of polymer film formed using a block copolymer constituted of hydrophilic polymer components and hydrophobic polymer components. The hydrophilic polymer components of the block copolymer have liquid crystallinity, and have a nature of orienting in a certain direction in the film to form a cylinder. Patent Reference 2 describes that the hydrophobic polymer components in the block copolymer have a fullerene at a terminal to be the electron donor, and by the hydrophilic polymer components forming a cylinder in the film, there is formed a structure in which the fullerene is regularly arrayed in the vicinity thereof. Note that Patent Reference 2 mentions that the polymer film can be applied to an organic thin film solar cell, but there is no specific description related to the electron donor phase.

Moreover, Non-Patent Reference 1 (Chem. Commun., 2010, 46, 6723-6725) describes a technology to form an organic thin film by using a block copolymer in which the fullerene is introduced into one of two types of molecule block units which are both π-conjugated, and apply it to the photoelectric conversion element. It describes that in the organic thin film formed by using the block copolymer, electron donor phases composed of molecule blocks in which the fullerene is introduced and electron acceptor phases composed of molecule blocks in which no fullerene is introduced are disposed regularly by self-organization. However, in Non-Patent Reference 1, with a film thickness which sufficiently ensures absorption of light, no measure is made for continuity of the electron acceptor phase and the electron donor phase in a film thickness direction.

Patent Reference 3 (Japanese Patent Application Laid-open No. 2011-216609) describes a technology related to a block copolymer constituted of an electron donating polymer chain and an electron accepting polymer chain, and a liquid-crystalline molecular structure is bonded to one of the polymer chains. The liquid-crystalline molecular structure described in Patent Reference 3 is bonded to a side chain and hence has a short conjugate length, and its charge transport characteristic is not high.

### SUMMARY OF THE INVENTION

It is an object of the present invention to provide a photoelectric conversion element with high photoelectric conversion efficiency, whose light absorption efficiency, charge separation efficiency, and charge transport efficiency are all at high level. It is another object of the present invention to provide a method for efficiently manufacturing the photoelectric conversion element.

A photoelectric conversion element of the present invention has an anode, a cathode opposed to the anode, and an organic film disposed between the anode and the cathode and containing a liquid-crystalline conjugated block polymer. A film thickness of the organic film which the photoelectric conversion element of the present invention has is preferably 200 nm to 1000 nm. In the photoelectric conversion element of the present invention, preferably, the organic film is a film formed by heating the liquid-crystalline conjugated block polymer at a temperature in a range in which the liquid-crystalline conjugated block polymer is in a liquid-crystalline state.

In the photoelectric conversion element of the present invention, preferably, the organic film is a film containing an electron acceptor and is a film containing as the liquid-crystalline conjugated block polymer a polymer constituted of a block having electron donating ability and a block compatible with the electron acceptor. In this case, preferably, the electron acceptor is a chemical compound selected from a fullerene and a derivative thereof.

In the photoelectric conversion element of the present invention, the organic film may be a film containing an electron donor and may be a film containing as the liquid-crystalline conjugated block polymer a polymer constituted of a block compatible with the electron donor and a block having electron acceptability. Moreover, the organic film may be a film containing as the liquid-crystalline conjugated block polymer a polymer constituted of a block having electron donating ability and a block having electron acceptability. In this case, the block having electron acceptability may be a block having a polymer unit which requires a fullerene structure.

In the photoelectric conversion element of the present invention, the liquid-crystalline conjugated block polymer may be constituted of a liquid crystal block and a non-liquid crystal block. In this case, the non-liquid crystal block may be constituted of a crystal block. The photoelectric conversion element of the present invention can be used for an organic thin film solar cell module.

The present invention also provides a method of manufacturing a photoelectric conversion element having an anode, a cathode opposed to the anode, and an organic film disposed between the anode and the cathode and containing a liquid-crystalline conjugated block polymer, including the steps of:

(1) preparing an organic film forming composition containing the liquid-crystalline conjugated block polymer;
(2) forming one of the anode and the cathode and forming a coating film by applying the organic film forming composition on one main surface of the electrode;
(3) heat treating the coating film within a temperature range in which the liquid-crystalline conjugated block polymer is in a liquid-crystalline state so as to obtain the organic film; and
(4) forming the other electrode which is not formed in the step (2) above the organic film.

In the manufacturing method of the present invention, preferably, the step (3) is performed after the step (4). Further, in the manufacturing method of the present invention, the photoelectric conversion element is an organic thin film solar cell.

According to the present invention, it is possible to provide a photoelectric conversion element with high photoelectric conversion efficiency, whose light absorption efficiency, charge separation efficiency, and charge transport efficiency are all at high level. By the manufacturing method of the present invention, the photoelectric conversion element of the present invention can be produced efficiently.

### BRIEF DESCRIPTION OF THE DRAWINGS

FIG. 1 is a cross-sectional view illustrating an example conceivable as an embodiment of the photoelectric conversion element of the present invention.

FIG. 2 is a cross-sectional view illustrating another example conceivable as an embodiment of the photoelectric conversion element of the present invention.

FIG. 3 is a perspective view including a cross section of an example of the case where the organic film illustrated in FIG. 1 has a lamellar structure.

FIG. 4A is a perspective view illustrating an example of the case where the organic film illustrated in FIG. 1 has a cylinder structure.

FIG. 4B is a perspective view including a cross section of an example of the organic film illustrated in FIG. 4A.

FIG. 4C is a perspective view including a cross section of another example of the organic film illustrated in FIG. 4A.

FIG. 5 is a cross-sectional view illustrating still another example conceivable as an embodiment of the photoelectric conversion element of the present invention.

FIG. 6A is a schematic view illustrating formation of a hydrophobic coating film by nanoimprinting.

FIG. 6B is a schematic view illustrating formation of a hydrophobic coating film by nanoimprinting.

FIG. 6C is a schematic view illustrating formation of a hydrophobic coating film by nanoimprinting.

FIG. 6D is a schematic view illustrating formation of a hydrophobic coating film by nanoimprinting.

### DETAILED DESCRIPTION

The photoelectric conversion element of the present invention has an anode, a cathode opposed to the anode, and an organic film disposed between the anode and the cathode and containing a liquid-crystalline conjugated block polymer. That is, the organic film according to the embodiments of the present invention contains a liquid-crystalline conjugated block polymer.

Here, the “block polymer” means a polymer having at least two types of block units. Here, the “block unit” indicates a unit of single polymer chain constituting the block polymer. The unit of single polymer chain need not necessarily be a homopolymer chain constituted of a single polymer unit, and may be a copolymer chain constituted of multiple polymer units (desirably, an alternating copolymer chain constituted of two types of polymer units). Further, a “conjugated polymer” means a polymer having a molecular structure to be π-conjugated in at least a main chain of the polymer chain. Further, the “conjugated block polymer” means one that is a block polymer and is also a conjugated polymer.

Further, the “liquid crystalline” means that a substance can take a liquid-crystalline state. That is, a substance can take a liquid-crystalline phase when changing from a solid phase to a liquid phase. Specifically, it refers to a nature having two phases transition points, a phase transition point (Tm or Tg) when changing from a solid phase to a liquid-crystalline phase and a phase transition point (Ti or Tc) when changing from a liquid-crystalline phase to a liquid phase. Note that a liquid-crystalline chemical compound can similarly take the liquid-crystalline phase also when changing from a liquid phase to a solid phase.

Hereinafter, “having liquid crystallinity” means the same as the “liquid crystalline”. “Non-liquid crystalline” means that a substance does not take the liquid-crystalline state. Further, the “non-liquid crystallinity” is divided into “crystallinity” and “amorphousness”. The “crystallinity” means that a solid phase becomes crystalline. The “amorphousness” means that a solid phase does not become crystalline.

A conjugated block polymer used for forming the organic film in the photoelectric conversion element according to the embodiments of the present invention needs to be liquid crystalline in its entirety. To make the conjugated block polymer be liquid crystalline, at least one of the two types of conjugated block units needs to be liquid crystalline. In this case, the other may be any of amorphous, liquid crystalline, and crystalline. Which of the two types of conjugated block units should be liquid crystalline and which of amorphous, liquid crystalline, and crystalline the other should be in this case are chosen appropriately as necessary. Note that a liquid-crystalline block unit is called a liquid crystal block in this description. The same applies to non-liquid crystalline, amorphous, and crystalline block units.

Note that when a polymer constituted of a single block unit is liquid crystalline, it is considered that the single block unit is a liquid crystal block. The same applies to non-liquid crystalline, amorphous, and crystalline block units.

In the photoelectric conversion element according to the embodiments of the present invention, block units constituting the conjugated block polymer used for forming the organic film are not limited as long as two or more types exist. However, a diblock copolymer constituted of two conjugated block units of two types or a triblock copolymer constituted of three conjugated block units of two types are preferred. Normally, as the diblock copolymer, there is used a diblock copolymer having an A-B structure in which one each of two types of block units A, B is bonded. Further, as the triblock copolymer, a triblock copolymer having a structure such as A-B-A or B-A-B is used. The diblock copolymer and the triblock copolymer may be used in combination.

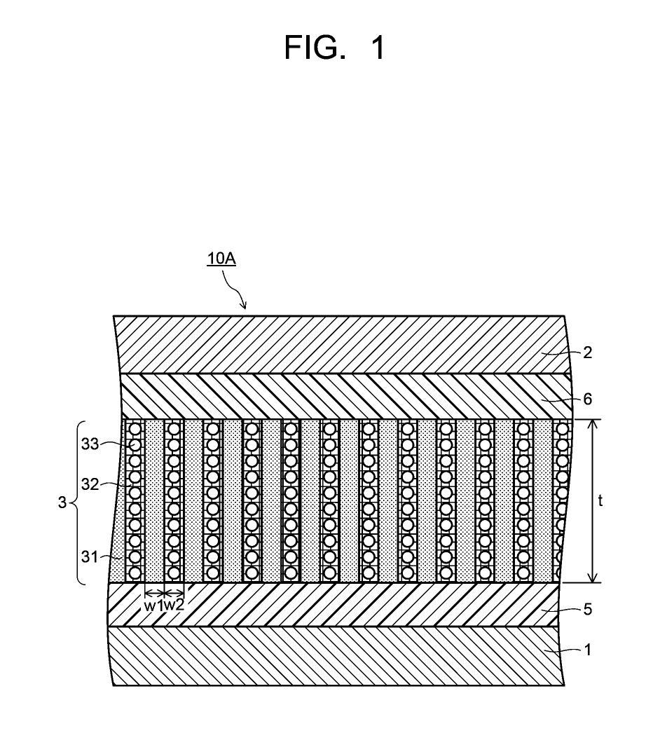

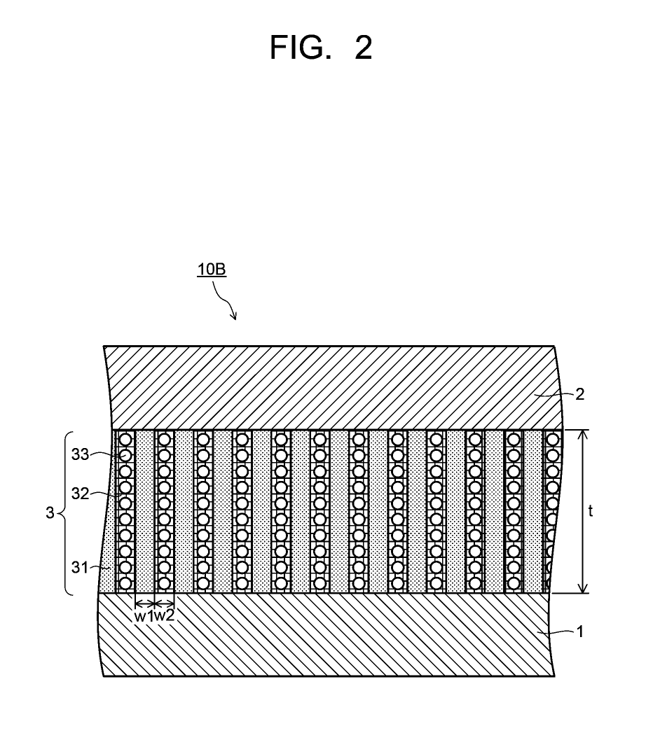

Hereinafter, an embodiment of the present invention will be described with reference to the drawings. Note that the present invention should not be construed to be limited to the following description. FIG. 1 is a cross-sectional view illustrating an example conceivable as an embodiment of the photoelectric conversion element of the present invention. Further, FIG. 2 is a cross-sectional view illustrating another example conceivable as an embodiment of the photoelectric conversion element of the present invention.

A photoelectric conversion element 10A, whose cross section is illustrated in FIG. 1, has an anode 1 and a cathode 2 opposing each other, and an organic film 3 disposed between the electrodes. The photoelectric conversion element 10A has a hole transport layer 5 for hindering transition of electrons to the anode, preventing short circuit, collecting holes, and the like between the anode 1 and the organic film 3, and an electron transport layer 6 for hindering transition of holes to the cathode, preventing short circuit, collecting electrons, and the like between the organic film 3 and the cathode 2.

A photoelectric conversion element 10B, whose cross section is illustrated in FIG. 2, has the same structure as the photoelectric conversion element 10A illustrated in FIG. 1 except that it does not have the hole transport layer 5 and the electron transport layer 6. Thus, the photoelectric conversion element according to the embodiments of the present invention may arbitrarily have various functional layers such as the hole transport layer and the electron transport layer which a photoelectric conversion element normally has within the range not impairing the effects of the present invention. The hole transport layer and the electron transport layer are functional layers which are particularly preferred to be provided in the photoelectric conversion element.

Features of the photoelectric conversion element according to the embodiments of the present invention reside in the following structure of the organic film 3. Conceivably, the organic film 3 is a film formed using a liquid-crystalline conjugated block polymer, preferably a film formed by heating a liquid-crystalline conjugated block polymer at a temperature within the range in which the block polymer is in a liquid-crystalline state, and is a film having regularly arrayed phases composed of block units of the conjugated block polymer.

Here, the “phase” used in this description refers to a nanoscale region having specific functions, formed of an aggregation of block units of the same type in the conjugated block polymer. Further, “phases composed of block units of the conjugated block polymer are regularly arrayed” means that, typically, by orientation of a liquid-crystalline conjugated block polymer constituted of two different types of conjugated block units, one block unit forms a region (phase) capable of transporting holes and simultaneously the other block unit forms a region (phase) capable of transporting electrons, and the phases appear periodically and at least one dimensionally so that the two regions (phases) are in an alternately aligned state.

Note that in this description, the “electron acceptor” means a substance or a portion receiving an electron in an electron transport reaction (oxidation-reduction reaction in a broad sense). That is, the electron acceptor has electron acceptability. Further, a chemical compound functioning as the electron acceptor is called “electron-accepting compound”. The “electron acceptor phase” means a phase having electron acceptability.

The “block having electron acceptability” means a block unit of the block polymer, the block unit having electron acceptability. In this description, this block unit is also called “electron-accepting block”. Further, a “block compatible with an electron acceptor” is called “electron acceptor compatible block”. Note that to be “compatible” means to have high affinity between the block and the electron acceptor. For example, the electron acceptor compatible block means that affinity between this block and the electron acceptor is high.

Further, in this description, the “electron donor” means a substance or a region donating an electron in an electron transport reaction (oxidation-reduction reaction in a broad sense). That is, the electron donor has electron donating ability. Further, a chemical compound functioning as the electron donor is called “electron-donating compound”. The “electron donor phase” means a phase having electron donating ability. Further, the “block having electron donating ability” means a block unit of the block polymer, the block unit having electron donating ability. In this description, this block unit is also called “electron-donating block”. Further, a “block compatible with an electron donor” is called “electron donor compatible block”.

In the organic film 3 illustrated in FIG. 1, the liquid-crystalline conjugated diblock copolymer is formed to be oriented in a direction orthogonal to the opposing electrodes, namely, main faces of the anode 1 and the cathode 2. Note that FIG. 1 illustrates a typical cross sectional state of the case assuming that the liquid-crystalline conjugated diblock copolymer is ideally arrayed in the entire region in formation of the organic film 3. This also applies to FIG. 2 to FIGS. 4A, 4B, 4C. Specifically, the diblock copolymer has its molecular surface in parallel with main surfaces of the electrodes, and respective block units A, B are stacked in a film thickness direction in a manner of aligning alternately. Thus, the film has a phase-separated structure in which phases 31 composed of block units A and phases 32 composed of block units B stand upright and arrayed regularly and alternately in the direction orthogonal to the main faces of the electrodes.

In this case, for example, the diblock copolymer may align alternately in the same molecular direction, such as A-B, A-B, A-B, or may align alternately in an alternated molecular direction, such as A-B, B-A, A-B. Assuming that molecules of the diblock copolymer are aligned linearly with each other in a molecular length direction, the width of each phase when the phases are aligned alternately in an alternated molecular direction is double that in the case where they are aligned alternately in the same molecular direction.

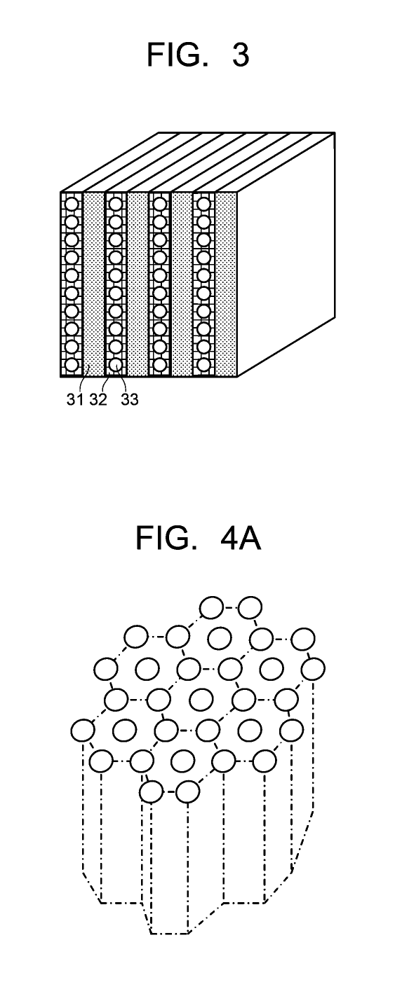

Such a regular phase-separated structure is formed by self-organization owing to that the conjugated diblock copolymer has liquid crystallinity. Specifically, they are formed by that the diblock copolymer has, for example, a lamellar structure or a cylinder structure. FIG. 3 schematically illustrates a typical example of the case where the organic film 3 has a lamellar structure by a perspective view including a cross section in a direction orthogonal to the main surfaces of the electrodes. In the lamellar structure, as illustrated in FIG. 3 for example, the phases 31 composed of block units A and the phases composed of block units B are formed both as a sheet-formed layer and have a stacked structure in which the phases stand upright.

Note that in the organic film used in the embodiments of the present invention, the “orthogonal direction” when the conjugated block polymer is oriented in a direction orthogonal to the opposing electrode faces and the direction “standing upright” when the phases composed of block units form the lamellar structure or cylinder structure standing upright in the orthogonal direction may be disordered within the range of not impairing functions in the photoelectric conversion element to be obtained, for example, light absorption efficiency and charge transport efficiency.

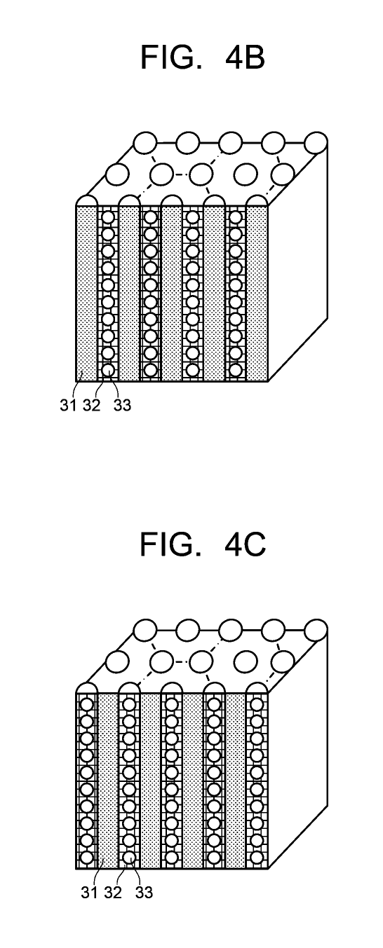

Further, the cylinder structure has a structure such that either the phase composed of block units A or the phase composed of block units B forms a phase in a columnar shape, a phase composed of block units not forming a column is formed in the periphery thereof, and these phases are arrayed regularly in repeated units. FIG. 4A schematically illustrates in a perspective view a typical example of the case where the organic film has the cylinder structure. FIG. 4B is a perspective view including a cross section of an example of the organic film illustrated in FIG. 4A, and FIG. 4C is a perspective view including a cross section of another example of the organic film illustrated in FIG. 4A.

With respect to the example illustrated in FIG. 4A, the example for which the perspective view including a cross section is illustrated in FIG. 4B, the block units A form the phases 31 in a columnar shape standing upright in the direction orthogonal to the main phases of the electrodes. The phases 31 in the columnar shape composed of block units A are formed at a center portion and at apexes of a virtual regular hexagon, and the periphery thereof is constituted of the phases 32 composed of block units B. Further, with respect to the example illustrated in FIG. 4A, the example for which the perspective view including a cross section is illustrated in FIG. 4C, the block units B form the phases 32 in a columnar shape standing upright in the direction orthogonal to the main phases of the electrodes. The phases 32 in the columnar shape composed of block units B are formed at a center portion and at apexes of a virtual regular hexagon, and the periphery thereof is constituted of the phases 31 composed of block units A.

When a cross section is taken along the direction orthogonal to the main surfaces of the electrodes of the organic film 3 as illustrated in FIG. 4B and FIG. 4C, the phase-separated structure is obtained in which the phases 31 composed of block units A and the phases 32 composed of block units B stand upright and are arrayed alternately and regularly in the direction orthogonal to the main phases of the electrodes, similarly to the cross sections illustrated in FIG. 1 and FIG. 3.

Here, the above description illustrates an ideal form of the organic film in nanoscale, and as long as the above-described phase-separated structure is substantially formed, there may be a partial disorder in the typical lamellar structure or cylinder structure illustrated in FIG. 3, FIG. 4A to FIG. 4C. For example, as will be described below, in the structures in FIG. 1 to FIG. 4C, the block units B are electron acceptor compatible blocks, and electron acceptors 33 are dispersed in the phases 32 composed of block units B. Here, when a fullerene, which will be described later, is used for example as the electron acceptors 33, the fullerene aggregates in micron to 100-micron order by heat treatment, and this may become a partial disorder in the regular phase-separated structure. However, even when such a partial disorder exists in the organic film, as long as the above-described phase-separated structure is formed which is regularly arrayed in most of the other region so that the light absorption efficiency and the electron transport efficiency can be maintained to a certainly high extent, this organic film can be used for photoelectric conversion element according to the embodiments of the present invention.

In the photoelectric conversion element 10A, the organic film 3 may function as an photoelectric conversion layer. Thus, in a preferred structure of the organic film 3, a film thickness represented by “t” in FIG. 1 is, as a range of satisfying both the light absorption efficiency and the electron transport efficiency, preferably in the range of 200 nm to 1000 nm, more preferably in the range of 200 nm to 500 nm, most preferably in the range of 200 nm to 300 nm. Note that high light absorption efficiency means that the organic film absorbs light sufficiently and does not transmit the light. That is, this means that, in this case, a sufficient number of excitons are generated.

In the organic film 3, the widths of the phases 31 composed of block units A and the phases 32 composed of block units B, which are provided alternately to stand upright with respect to the electrode surfaces, depend on chain lengths of the respective block units. In the photoelectric conversion element 10A, the organic film 3 functions as a photoelectric conversion layer. The photoelectric conversion element 10A is structured such that, in order to give a photoelectric conversion function to the organic film 3, the block units A of the conjugated diblock copolymer are electron-donating blocks, the block units B are electron acceptor compatible blocks, and further the electron acceptors 33 are dispersed in the phases 32 formed of electron acceptor compatible blocks.

In the above-described structure, the phases 31 composed of block units A function as electron donor phases, and the phases 32 composed of block units B containing the electron acceptors 33 function as electron acceptor phases. Therefore, all the widths of phases represented by w1 and w2 in FIG. 1 are preferably 8 nm to 50 nm, more preferably 10 nm to 30 nm, in consideration of charge separation efficiency. Note that in a strict sense, the charge separation includes two types of elementary processes of charge separation and charge deviation, but in this description they are both referred to as charge separation.

Here, the respective widths w1 and w2 of the phases can be adjusted by adjusting the polymer units and the degree of polymerization which constitute the block units A and the block units B used for manufacturing the conjugated diblock copolymer. For example, when the conjugated diblock copolymer is aligned alternately in the same molecular direction such as A-B, A-B, A-B, it is just necessary to conduct molecular design so that the lengths of block units A and block units B match the widths w1 and w2. Further, when it is aligned alternately in the alternated molecular direction such as A-B, B-A, A-B, molecular design is conducted so that the lengths of block units A and block units B are half the w1 and w2, respectively. How the conjugated diblock copolymer is aligned depends on the types of the block units A and the block units B.

Note that w1:w2 which is the ratio of the widths of the phases 31 composed of block units A and the phases 32 composed of block units B, namely, the ratio of chain lengths of block units of the block units A and the block units B is preferably 10:90 to 90:10, more preferably 30:70 to 70:30. Although it depends on the degree of polymerization of the conjugated block polymer and the compatibility between the block units A and the block units B, the ratio w1:w2 set in the above range causes the array of phases to form the cylinder structure or the lamellar structure.

In the organic film 3 which the photoelectric conversion element 10A has, the phases 31 composed of block units A constituted of electron-donating blocks are electron donor phases, and the phases 32 composed of block units B constituted of electron acceptor compatible blocks in a state of containing the electron acceptors 33 are electron acceptor phases. Note that the block units A and the block units B may be interchanged, so that the block units A are the electron acceptor compatible blocks and the block units B are the electron-donating blocks. In this case, the phases composed of block units B become the electron donor phases, and the phases composed of block units A contain the electron acceptors to become the electron acceptor phases.

As another mode of the organic film 3, a structure may be mentioned in which block units A of the conjugated diblock copolymer are electron donor compatible blocks, block units B of the conjugated diblock copolymer are electron-accepting blocks, and further electron donors are dispersed in phases formed of the electron donor compatible blocks. As still another mode, a structure may be mentioned in which block units A of the conjugated diblock copolymer are electron-donating blocks, and block units B of the conjugated diblock copolymer are electron-accepting blocks. Note that also in the structures of these modes, the block units A and the block units B may be interchanged similarly to the above.

Thus, in the photoelectric conversion element according to the embodiments of the present invention, the organic film having a photoelectric conversion function formed between the opposing anode and cathode is formed by combining the liquid-crystalline conjugated block polymer and electron donors or electron acceptors as necessary. The conjugated block polymer used is preferably the diblock copolymer constituted of two types of conjugated block units as described above. As the two types of block units, specifically, as described above, there may be mentioned a combination of electron-donating blocks and electron acceptor compatible blocks, a combination of electron donor compatible blocks and electron-accepting blocks, and a combination of electron-donating blocks and electron-accepting blocks.

In the conjugated diblock copolymer, the two types of conjugated block units both have a molecular structure to be π-conjugated to a main chain or side chain of a polymer constituting the block units. The molecular structure to be π-conjugated may be the same or different in the two-types of conjugated block units.

As the molecular structure to be π-conjugated, specifically, there may be mentioned a structure including an aromatic ring. As the aromatic ring, there may be mentioned a 6-membered ring and a 5-membered ring. As the molecular structure to be π-conjugated, there may be mentioned monocyclic structures, polycyclic aggregate structures, fused polycyclic structures, and the like of the 6-membered ring and the 5-membered ring. The aromatic ring may be a heterocyclic ring containing a heteroatom or heteroatoms. As the heteroatoms, there may be mentioned chalcogen atoms such as oxygen atom, sulfur atom, selenium atom, and tellurium atom, as well as nitrogen atom, phosphorus atom, and so on. The combination and the number of heteroatoms in the heterocyclic ring are not particularly limited.

As the heterocyclic ring, one containing a chalcogen atom or atoms is preferred. Further, the heterocyclic ring containing a chalcogen atom or atoms may include a heteroatom or heteroatoms other than chalcogen atoms, such as a nitrogen atom. As the chalcogen atom, the sulfur atom is preferred. The number of sulfur atoms in the aromatic ring is preferred to be one or two.

Here, the conjugated block polymer used in the photoelectric conversion element according to the embodiments of the present invention has liquid crystallinity. For this purpose, at least one of the two types of conjugated block units needs to have liquid crystallinity. When the aromatic ring structures of the conjugated block units do not have liquid crystallinity, a substituent that contributes to exhibition of liquid crystallinity is appropriately selected and introduced into the aromatic ring of at least one of the conjugated block units, which is not necessary when the structures have liquid crystallinity.

Note that whether or not to exhibit liquid crystallinity is not determined only by the substituent to be introduced, but is determined by a structure combining the main chain into which it is introduced and the substituent to be introduced. Here, the liquid-crystalline conjugated block polymer used for the photoelectric conversion element according to the embodiments of the present invention may be formed as the organic film 3 by heating this block polymer at a temperature in the range it is in a liquid-crystalline state. In the photoelectric conversion element according to the embodiments of the present invention, in view of productivity, reliability and operating stability of the photoelectric conversion element, and the like, a temperature range in which the conjugated block polymer is in a liquid-crystalline state is preferably 100° C. to 300° C., more preferably 150° C. to 250° C. Therefore, when molecular design of the conjugated block unit is conducted, the molecular design is preferred to be conducted so that liquid crystallinity is exhibited in this temperature range.

In general, there is a tendency that amorphousness increases when an alkyl group is introduced as the substituent into the aromatic ring structure. Specifically, it is known that when the main chain with no substituent is crystalline, it changes in a direction to exhibit liquid crystallinity when an alkyl group is introduced into a side chain. Further, when a molecular length of the alkyl group is long, it tends to be amorphous, or when the alkyl group is a straight chain or a branch structure, one having the branch structure tends to be amorphous. Taking these relations and whether the main chain is crystalline or amorphous into consideration, a substituent to be introduced for exhibiting liquid crystallinity is selected appropriately.

As such a substituent, specifically, there may be mentioned an alkyl group, a fluorine-containing alkyl group, and the like having a straight, annular or branched chain with 1 to 24 carbon atoms, which may have an ether bond (—O—) or ester bond (—C(═O)O—, —OC(═O)—) between carbon atoms or at a terminal on the side bonded to the aromatic ring. As the alkyl group, one having a straight chain or branched chain is preferred, and its number of carbon atoms is preferably 3 to 20, more preferably 6 to 16.

Among them, more preferred ones are isopropyl group, isobutyl group, sec-butyl group, pentyl group, isopentyl group, 2-methylbutyl group, 1,1-dimethylpropyl group, 2,2-dimethylpropyl group, hexyl group, heptyl group, octyl group, 2-ethylhexyl group, 3,7-dimethyloctyl group, dodecyl group, hexadecyl group, 2-butyloctyl group, 2-hexyldecyl group, 2-octyl dodecyl group, 2-decyltetradecyl group, and particularly preferred ones are hexyl group, octyl group, 2-ethylhexyl group, 2-hexyldecyl group. Note that they may have an ether bond (—O—) or ester bond (—C(═O)O—, —OC(═O)—) at a terminal on the side bonded to the aromatic ring.

Further, depending on various purposes, the aromatic ring may have a substituent other than the above substituents contributing to exhibition of liquid crystallinity. As such a substituent, there may be mentioned a fluorine atom, and the like.

Besides a structure having two or more monocycles of the same or different types bonded via a single bond, the polycyclic aggregate structure may be a structure bonded via an oxygen atom, sulfur atom, nitrogen atom, or the like instead of the single bond. Moreover, the monocycles may be bonded with each other either via one of ring constituting atoms or via two or more thereof.

Each of the two types of conjugated block units constituting the conjugated diblock copolymer is a polymer chain containing a polymer unit having a molecular structure to be it conjugated. The two types of conjugated block units are not particularly limited as long as they are of different types. Therefore, the two types of conjugated block units may be ones having a completely different π-conjugated molecular structure, but are preferred to have moderate compatibility in order to make arrays of two phases formed by them constitute the cylinder structure or the lamellar structure. For this purpose, the two types of conjugated block units are preferably ones having same or similar molecular structures of a skeleton to be π-conjugated and having different substituents. Specific combinations will be described later.

The conjugated block units may be homopolymer chains constituted of one type selected from the polymer units having a molecular structure to be π-conjugated, or copolymer chains combining two or more types. Moreover, as necessary, they may be copolymer chains containing a polymer unit having a molecular structure which is not π-conjugated. In the case of the copolymer chains, they may be alternating copolymer chains or block copolymer chains (however, the number of polymer units constituting the blocks is four or less). Further, when the conjugated block units have a fused polycyclic structure, it may be either one formed by polymerization of monomers having a fused polycyclic structure or one formed by fused ring polymerization of monomers whose rings are fused by polymerization. Preferably, the conjugated block units are constituted of the homopolymer chain.

As the polymer unit having only a 6-membered ring as an aromatic ring, there may be mentioned phenylene, phenylenevinylene, aniline, pyrimidine, pyrazine, triazine, and the like which may have the above-described substituent. As the conjugated block units which have them as polymer units, there may be mentioned a homopolymer chain having only a phenylene polymer unit of polyphenylene or the like, a homopolymer chain having only a phenylenevinylene polymer unit, a homopolymer chain having only an aniline polymer unit of polyaniline or the like, and the like. Note that these homopolymer chains may each be a homopolymer chain constituted of a polymer unit of phenylene, phenylenevinylene, aniline, or the like which has the above-described substituent.

Among them, preferred ones are poly[2-methoxy-5-(2-ethylhexyloxy)-1,4-phenylenevinylene]), poly[2-methoxy-5-(3′,7′-dimethoxyoctyloxy)-1,4-phenylenevinylene]).

As the polymer unit having only 5-membered ring as an aromatic ring, there may be mentioned thiophene, thiazole, and the like having a sulfur atom or atoms as heteroatoms, and pyrrole, pyrazole, and the like having a nitrogen atom or atoms as heteroatoms. They may likewise have the above-described substituent. Further, they may have a polycyclic aggregate structure. As the polymer unit having the polycyclic aggregate structure, there may be mentioned bithiophene, and the like.

As the fused ring structure containing two or more rings as an aromatic ring structure, there may be mentioned naphthalene, anthracene, phenanthrene, fluorene, dibenzosilole, carbazole, and the like which may have the above-described substituent. As the conjugated block unit having them as polymer units, a homopolymer chain of fluorene which may have the above-described substituent is preferred.

As the homopolymer chain of fluorene which may have the substituent, preferred ones are poly(9,9-dioctylfluorenyl-2,7-diyl), poly[9,9-di(2-ethylhexyl)fluorenyl-2,7-diyl], and the like. Note that all of them are liquid-crystalline conjugated block units.

Further, as the fused ring structure having a sulfur atom or atoms, there may be mentioned benzothiadiazole, dithienylbenzothiadiazole, thienothiophene, thienopyrrole, benzodithiophene, dibenzothiophene, dinaphthothienothiophene, benzothieno benzothiophene, cyclopentadithiophene, dithienosilole, thiazolothiazole, tetrathiafulvalene, and the like which may have the above-described substituent. Note that these chemical compounds exist in the form of bivalent group as a polymer unit in the polymer chain constituting the conjugated block unit.

As the polymer chain having a monocycle structure having a sulfur atom or atoms, there may be mentioned a homopolymer chain of thiophene which may have a substituent, and a copolymer chain having a thiophene polymer unit which may have a substituent and a phenylene polymer unit which may have a substituent. Among them, the homopolymer chain of thiophene which may have a substituent is preferred, and specifically, poly(3-hexylthiophene), poly(3-octylthiophene), and the like are preferred.

As the copolymer chain having a sulfur atom or atoms and having a fused ring structure, there may be mentioned a copolymer chain of thiophene and fluorene, a copolymer chain of thiophene and thienothiophene, a copolymer chain of thiophene and thiazolothiazole, a copolymer chain of cyclopentadithiophene and thienothiophene, a copolymer chain of dithienosilole and benzothiadiazole, a copolymer chain of fluorene and dithienylbenzothiadiazole, a copolymer chain of fluorene and benzothiadiazole, a copolymer chain of dibenzosilole and dithienylbenzothiadiazole, a copolymer chain of carbazole and dithienylbenzothiadiazole, a copolymer chain of benzodithiophene and thienopyrrole, a copolymer chain of benzodithiophene and thienothiophene, a copolymer chain of fluorene and bithiophene, and the like.

Among them, preferred ones are an alternating copolymer chain of thiophene and thienothiophene, an alternating copolymer chain of fluorene and benzothiadiazole, an alternating copolymer chain of fluorene and bithiophene, and the like. Note that all of them may have a substituent similar to the above ones.

There may be mentioned poly(2,5-bis-(3-dodecylthiophene-2-yl)thieno[3,2-b]thiophene), and poly(2,5-bis-(3-hexadecylthiophene-2-yl)thieno[3,2-b]thiophene) as the alternating copolymer chain of thiophene and thienothiophene, poly[(9,9-di-n-octylfluorenyl-2,7-diyl)-ortho-(benzo[2,1,3]thiadiazole-4,8-diyl)] as the alternating copolymer chain of fluorene and benzothiadiazole, and poly[(9,9-dioctylfluorenyl-2,7-diyl)-co-bithiophene] as the alternating copolymer chain of fluorene and bithiophene. Note that all of them are liquid-crystalline conjugated block units.

Note that in order to allow stable retaining of the state that the conjugated block polymer is oriented when forming the organic film, the above-described conjugated block units may be structured to have a group having a cross-linking group in a side chain. As the cross-linking group, any functional group which cross-links by heat or light may be mentioned without any particular limit. In the case of the functional group which cross-links by heat, cross-linking may occur by heating before orientation occurs, and hence the functional group which cross-links by light is preferred. As such a functional group, there may be mentioned an acryloxy group, a methacryloxy group, a vinyl group, an oxetane group, and the like.

Further, when performing a hydrophobic treatment on a region where a phase containing the electron acceptor is formed on an organic film forming surface by a nanoimprint method which will be described later, preferably, a hydrophobic substituent such as fluorine atom, a fluorine-containing alkyl group, or the like is introduced into the electron acceptor compatible block and/or the electron-donating block.

The polymer chains having a π-conjugated molecular structure to be the conjugated block unit constituting the liquid-crystalline conjugated block polymer have been described above. Since these polymer chains have a π-conjugated molecular structure, they can be used as electron-donating blocks as they are. Further, when the electron-donating blocks are used in the conjugated block polymer, in order to give a photoelectric conversion element function to the obtained organic film, an electron acceptor compatible block or an electron-accepting block is used in combination with this block. Note that when the electron acceptor compatible block is used, the organic film is formed by combining the conjugated block polymer and electron acceptors, making a form such that the phases constituted of the electron acceptor compatible blocks contain the electron acceptors.

Here, in order to obtain an organic film having the above-described structure which is regularly phase separated and arrayed, preferably, the conjugated block units constituting the conjugated block polymer have moderate compatibility with each other. Further, when the polymer chains having a π-conjugated molecular structure are used as electron-donating blocks, for electron-accepting blocks having the following molecular structure for being used in combination with the blocks to operate as electron acceptors, it is difficult to set conditions in view of ensuring compatibility by having a molecular structure similar to the electron-donating blocks. Thus, use of electron acceptor compatible blocks which can be constituted of the polymer chains having a π-conjugated molecular structure is preferred for obtaining the above-described structure which is regularly phase separated and arrayed.

When the electron acceptor compatible blocks are used in combination with the electron-donating blocks, polymer chains which are different from the polymer chains selected as the electron-donating blocks from the above-described polymer chains but have sufficient compatibility and structural similarity for obtaining the above-described structure which is regularly phase separated and arrayed can be selected and used as the electron acceptor compatible blocks. Further, as the electron acceptor compatible blocks, ones which are more compatible with the electron acceptors than the conjugated block units constituting the electron-donating blocks are selected and used appropriately from the conjugated block units exemplified above.

Further, when the polymer chains having a π-conjugated molecular structure used as the electron-donating blocks, compounds satisfying the following relation may be mentioned as an electron-accepting compound to be combined.

Regarding the relation of energy level between the electron donor and the electron acceptor, it is required that energy level of LUMO (excited state) of the electron acceptors is lower than energy level of LUMO (excited state) of the electron donors and is higher than energy level of HOMO (ground state) of the electron donors, and it is required that energy level of HOMO (ground state) of the electron acceptors is lower than the energy level of the HOMO (ground state) of the electron donors.

From this relation, as the electron-accepting compound used in combination with the electron-donating blocks, preferably, there may be mentioned a fullerene and derivative thereof, perylene and derivative thereof, naphthalene and derivative thereof, carbon nanotubes, and the like. Among them, the fullerene and derivative thereof are particularly preferred.

As the fullerene, there may be mentioned a high-order fullerene such as fullerene (C₆₀), fullerene (C₇₀), fullerene (C₈₀), fullerene (C₈₄), fullerene (C₁₂₀), and so on. As the fullerene derivative, there may be mentioned (6,6)-phenyl-C₆₁-butyric acid methyl ester (PC60BM), (6,6)-phenyl-C₇₁-butyric acid methyl ester (PC70BM), (6,6)-thienyl-C₆₁-butyric acid methyl ester (ThCBM), and the like. Among them, the fullerene (C₆₀), PC60BM, PC70BM may be mentioned as preferred ones.

In short, in the photoelectric conversion element according to the embodiments of the present invention, when the conjugated block polymer constituted of electron-donating blocks and electron acceptor compatible blocks is used, and the organic film is formed by combining this conjugated block polymer with electron acceptors, the relation among the electron-donating blocks, the electron acceptor compatible blocks, and the electron-accepting compound is as follows.

(a) In order to make the organic film having the structure which is regularly phase separated and arrayed, the electron-donating blocks and the electron acceptor compatible blocks have moderate compatibility.
(b) Compared to the electron-donating blocks, the electron acceptor compatible blocks excel in compatibility with the electron-accepting compound.
(c) The relation of energy level of the electron-donating blocks and the electron-accepting compound is as described above.

Further, in order to make the organic film having the structure which is regularly phase separated and arrayed, preferably, one of the electron-donating blocks and the electron acceptor compatible blocks has liquid crystallinity and the other is non-liquid crystalline. When the electron-donating blocks are liquid crystalline, preferably, the electron acceptor compatible blocks are crystalline or amorphous, more preferably amorphous.

As the electron-donating blocks when the electron-donating blocks are liquid crystalline, specifically, there may be mentioned a copolymer chain of thiophene and thienothiophene, a copolymer chain of benzothiadiazole and fluorene, a copolymer chain of thiophene and fluorene, and the like which may have a substituent similar to the above ones in polymer units of the above copolymer chains. Note that when the electron-donating blocks are the liquid-crystalline conjugated block units, molecular design is carried out so that the entire conjugated block units become liquid crystalline, and a substituent contributing to exhibition of liquid crystallinity is selected in line with the design. Note that as more specific conjugated block units, there may be mentioned conjugated block units similar to those exemplified above.

As the electron acceptor compatible blocks, specifically, there may be mentioned a copolymer chain of thiophene and thienothiophene, a copolymer of benzothiadiazole and fluorene, a copolymer chain of thiophene and fluorene, and the like which has a substituent different from the electron-donating blocks in polymer units of the above copolymers.

When the electron-donating blocks have liquid crystallinity, preferably, the electron acceptor compatible blocks are amorphous because this makes it easy to obtain the organic film having the structure which is regularly phase separated and arrayed. In this case, the substituent which the electron acceptor compatible blocks have preferably has a more branched structure compared to the substituent which the electron-donating blocks have. When the electron-donating blocks do not have the substituent, a straight-chain alkyl group or an alkyl group having a branched chain is preferred as the substituent in the electron acceptor compatible blocks. When the electron-donating blocks have the straight-chain alkyl group as the substituent, an alkyl group having a branched chain is preferred as the substituent in the electron acceptor compatible blocks. When the electron-donating blocks have the alkyl group having a branched chain as the substituent, an alkyl group having a branched chain which is more branched or an alkyl group having a longer branched chain is preferred as the substituent in the electron acceptor compatible blocks.

Among them, as a preferred combination, there may be mentioned a combination such that the electron-donating blocks have a straight-chain alkyl group (number of carbon atoms is 4 to 24) as the substituent, and the electron acceptor compatible blocks have a 2-ethylhexyl group or 2-hexyldecyl group as the substituent.

On the other hand, when the electron acceptor compatible blocks are liquid crystalline, preferably, the electron-donating blocks are non-liquid crystalline, that is, crystalline or amorphous, more preferably crystalline. Regarding the electron-donating blocks, crystal blocks are higher in charge mobility than amorphous blocks, and can result in high charge mobility as the entire conjugated block polymer.

As the electron acceptor compatible blocks when the electron acceptor compatible blocks are liquid crystalline, specifically, there may be mentioned a copolymer chain of thiophene and thienothiophene, a copolymer chain of benzothiadiazole and fluorene, a copolymer chain of thiophene and fluorine, a homopolymer chain of fluorene, and the like, which may have a substituent similar to the above ones in polymer units of the above copolymer or homopolymer chains. Note that when the electron acceptor compatible blocks are the liquid-crystalline conjugated block units, molecular design is carried out so that the entire conjugated block units become liquid crystalline, and a substituent contributing to exhibition of liquid crystallinity is selected in line with the design. As more specific electron acceptor compatible block units, there may be mentioned a homopolymer chain of fluorene which may have a substituent, for example, poly(9,9-dioctylfluorenyl-2,7-diyl) and the like.

As described above, the electron-donating blocks in this case are preferably non-liquid crystalline, more preferably crystalline. As the crystalline electron-donating blocks, specifically, there may be mentioned a homopolymer chain of thiophene which may have a substituent similar to the above ones, a homopolymer chain of cyclopentadithiophene which may have a substituent, a homopolymer chain of benzodithiophene which may have a substituent, a homopolymer chain of thienothiophene which may have a substituent, a homopolymer chain of dithienylbenzothiadiazole which may have a substituent in polymer units of the above homopolymer chains, and the like. As more specific electron-donating block units, there may be mentioned a homopolymer chain of thiophene, for example poly(3-hexylthiophene) or the like, which may have a substituent.

The degrees of polymerization of the conjugated block units are each adjusted as follows with respect to the two types of conjugated block units, according to the type of a material monomer to be used for polymerization. When the conjugated block polymer is arrayed alternately in the same molecular direction such as A-B, A-B, A-B upon film formation, it is adjusted so that chain lengths of the block units are equal to, for example, the width w1 of the phases 31 composed of block units A, the width w2 of the phases 32 composed of block units B, respectively, in the organic film 3 illustrated in FIG. 1. Further, when the conjugated block polymer is arrayed in the alternated molecular direction such as A-B, B-A, A-B upon film formation, the degrees of polymerization of the conjugated block units are adjusted so that chain lengths with respect to the two types of conjugated block units become half the width w1 of the phases 31 and half the width w2 of the phases 32, respectively. Although depending on the type of material monomer used for polymerization and the manner of arraying upon film formation as the conjugated block polymer, the degrees of polymerization are preferably 5 to 300, more preferably 10 to 100.

Further, the molecular weights of the conjugated block units are determined by the types of monomers used respectively for polymerization of the two types of conjugated block units and the degrees of polymerization. Such molecular weights of the conjugated block units are preferably 500 to 50,000, more preferably 2,000 to 20,000 for the two types of conjugated block units.

Upon film formation of the conjugated block polymer constituted of the electron-donating blocks and the electron acceptor compatible blocks, the above-described electron-accepting compound is added. At this time, the amount of the electron-accepting compound to be used is preferably 0.1 to 3 parts by mass, more preferably 0.3 to 1.5 parts by mass relative to one part by mass of the conjugated block polymer.

The conjugated block polymer constituted of the electron-donating blocks and the electron acceptor compatible blocks as described above is preferably used for producing the organic film, but an organic film using a conjugated block polymer constituted of electron-donating blocks and electron-accepting blocks may be produced as necessary. In this case, the electron-accepting blocks can be obtained by introducing into the polymer chains having a π-conjugated molecule structure exemplified above a molecule structure for operating as electron acceptors when combined with the electron-donating blocks to be used.

Specifically, the electron-accepting blocks can be obtained by copolymerizing a material monomer of the polymer chains having a π-conjugated molecular structure and a monomer which has an electron-accepting group in a side chain and which is polymerization reactive to the material monomer. Note that in the monomer the electron-accepting group is introduced as an electron-accepting monovalent group as part of the monomer. As the electron-accepting group, there may be mentioned a group having the same structure as a compound similar to those described above as the electron-accepting compound to be used by dispersing in the phases of the electron acceptor compatible blocks, for example a group having a fullerene structure such as a fullerene or derivative thereof, and a preferred mode can also be similar to the above-described one. Specifically, as the electron-accepting blocks, blocks having polymer units which require the fullerene structure is preferred.

These monomers having an electron-accepting group in a side chain are selected appropriately by the material monomer of the polymer chains having a π-conjugated molecular structure. A monomer in which an electron-accepting group is introduced into side chains of the material monomer of the polymer chains is most typically used. Note that any monomer can be used without any particular limitation as long as it is a monomer capable of copolymerizing with the material monomer of the polymer chains and is a monomer in which the electron-accepting group can be introduced into side chains. Note that the electron-accepting group may be introduced in the stage of monomer, but may also be introduced in the stage of polymer. As a method for introducing the electron-accepting group in the stage of polymer, there may be mentioned a method to synthesize the polymer using a monomer having a functional group replaceable with an electron-accepting group, and to replace the functional group replaceable with an electron-accepting group with the electron-accepting group.

Here, the ratio of the electron-accepting compound to be introduced into the polymer chains of the block units having a π-conjugated molecular structure is, as a ratio of a monomer having the electron-accepting compound group in a side chain to one mole of the material monomer of the polymer chains, preferably 0.1 to 5 moles, more preferably 0.3 to 2 moles.

The degrees of polymerization of the electron-accepting blocks and the electron-donating blocks are each adjusted as follows with respect to chain lengths of the two types of block units according to the type of a material monomer to be used for polymerization. When the conjugated block polymer is arrayed alternately in the same molecular direction such as A-B, A-B, A-B upon film formation, they are adjusted to be equal to, for example, the width w1 of the phases 31 composed of block units A or the width w2 of the phases 32 composed of block units B, respectively, in the organic film 3 illustrated in FIG. 1. Further, when the conjugated block polymer is arrayed in the alternated molecular direction such as A-B, B-A, A-B upon film formation, the degrees of polymerization of the conjugated block units are adjusted so that chain lengths with respect to the two types of conjugated block units become half the width w1 of the phases 31 and half the width w2 of the phases 32, respectively. Although depending on the type of material monomer used for polymerization and the manner of arraying upon film formation as the conjugated block polymer, the degrees of polymerization are preferably 5 to 300, more preferably 10 to 100.

Further, the molecular weights of the electron-accepting blocks are determined by the type of monomer used for polymerization and the degrees of polymerization. The electron-accepting compound group which the electron-accepting blocks have often has a high molecular weight similarly to, for example, the fullerene and the derivative thereof, and therefore, the molecular weights of the electron-accepting blocks are preferably 500 to 50,000, more preferably 2,000 to 20,000.

As described above, the conjugated block polymer preferably has a structure in which one each of the two types of conjugated block units is bonded. The two types of conjugated block units to be combined are as described above.

Besides the above ones, as another combination of the two types of conjugated block units in the conjugated block polymer, a combination formed of electron donor compatible blocks and electron-accepting blocks may be mentioned. In this case, electron donors are further added upon forming the organic film, which are used in the form of being dispersed in electron donor compatible block phases. In this case, as the electron-accepting blocks, there may be mentioned a polymer chain whose polymer unit is perylenediimide, naphthalenediimide, benzobisimidazo phenanthroline, diketo-pyrrolo-pyrrole, and the like which may have a substituent as the conjugated block unit. In this case, as the electron donor compatible blocks, one having the same or similar skeletal molecular structure to be π-conjugated with the electron-accepting blocks and having a different substituent is desirable. Further, as the electron donors to be used, there may be mentioned an oligomer of an electron-donating compound whose degree of polymerization is 3 to 10, for example, oligothiophene, oligo phenylenevinylene, phthalocyanine compound, porphyrin compound, and the like. The amount of electron donors to be used is preferably 0.1 to 3 parts by mass, more preferably 0.3 to 0.8 parts by mass relative to one part by mass of the conjugated block polymer.

The conjugated block polymer can be obtained by, for example, polymerizing one of the two types of conjugated block units using a material monomer to be its polymer unit by a conventional publicly known method until it has a desired degree of polymerization and molecular length, thereafter adding thereto a material monomer to be a polymer unit constituting the other conjugated block units, and polymerizing until it has a desired degree of polymerization and molecular length in a form continuous to the conjugated block units which are polymerized first. Further, regarding the conjugated block units which are obtained by polymerizing the two types of conjugated block units separately from material monomers until they have a desired degree of polymerization and molecular length similarly to the above, a functional group which reacts with one terminal to be bonded thereto may be introduced to each of them to let this reaction occur.

The molecular length of the obtained conjugated block polymer is the above-described w1+w2 or w1/2+w2/2 depending on the manner of arraying the conjugated block polymer during film formation. Specifically, the molecular length is preferably 20 nm to 100 nm, more preferably 30 nm to 60 nm. Further, the molecular weight of the conjugated block polymer is substantially equal to the sum of the two types of conjugated block units, and in the case of the combination of electron-donating blocks and electron acceptor compatible blocks, it is preferably 1,000 to 1,000,000. The molecular weight is more preferably 10,000 to 50,000. Further, in the case of the combination of electron-donating blocks and electron-accepting blocks, it is preferably 1,000 to 1,000,000, more preferably 10,000 to 50,000 similarly to above.

Note that regarding a method of forming the organic film using such a liquid-crystalline conjugated block polymer and electron donors and/or electron acceptors as necessary, for example, the organic film can be produced through steps (1) to (3) in a manufacturing method of a photoelectric conversion element of the present invention which will be described below.

A method of manufacturing a photoelectric conversion element of the present invention, the photoelectric conversion element having an anode, a cathode opposed to the anode, and an organic film disposed between the anode and the cathode and containing a liquid-crystalline conjugated block polymer, has the step of:

(1) preparing an organic film forming composition containing the liquid-crystalline conjugated block polymer (hereinafter referred to as “organic film forming composition preparing step”);
(2) forming one of the anode and the cathode and forming a coating film by applying the organic film forming composition on one main surface of the electrode (hereinafter referred to as “coating film forming step”);
(3) heat treating the coating film within a temperature range in which the liquid-crystalline conjugated block polymer is in a liquid-crystalline state so as to obtain the organic film (hereinafter referred to as “heat treatment step”); and
(4) forming the other electrode which is not formed in the step (2) above the organic film (hereinafter referred to as “electrode forming step”).

In the manufacturing method of the photoelectric conversion element according to the embodiments of the present invention, regarding the order of performing (1) organic film forming composition preparing step, (2) coating film forming step, (3) heat treatment step, and (4) electrode forming step, they may be performed in the order of (1), (2), (3), (4), or may be performed in the order of (1), (2), (4), (3). In view of making the electrode and the organic layer adapt to each other to decrease contact resistance and thereby increase photoelectric conversion efficiency, performing in the order of (1), (2), (4), (3) is preferred.

The respective steps will be described below.

### (1) Organic Film Forming Composition Preparing Step

The organic film forming composition is constituted of solid components for forming the organic film and a solvent. The components for forming the organic film are the liquid-crystalline conjugated block polymer and electron acceptor or electron donor as necessary.

When the liquid-crystalline conjugated block polymer is constituted of electron-donating blocks and electron acceptor compatible blocks, the composition contains electron acceptors. When the conjugated block polymer is constituted of electron-donating blocks and electron-accepting blocks, the solid components may be only them. When the conjugated block polymer is constituted of electron donor compatible blocks and electron-accepting blocks, the composition contains electron donors. Types and amounts of these conjugated block polymers and the electron acceptors, electron donors, and/or the like to be combined are as described above.

As other solid components, the organic film forming composition may contain ultraviolet absorbent, antioxidant, light stabilizer, surfactant, repelling preventing agent, and/or the like as necessary within the range not impairing the effects of the embodiments of the present invention. Each of these arbitrary components may be blended by five parts by mass relative to 100 parts by mass of the amounts of required solid components, although depending on the types of arbitrary components.

In the organic film forming composition, the solvent to dissolve or disperse these solid components are selected appropriately according to these solid components. As typical examples, it is possible to select from esters, ethers, ketones, alcohols, polyalcohol derivatives, aromatic hydrocarbons, and the like. Among them, esters and aromatic hydrocarbons with a boiling point of 250° C. or lower are preferred, and among them, solvents with a boiling point of 150° C. or lower are more preferred. Specifically, benzene, toluene, chlorobenzene, dichlorobenzene, mesitylene, acetophenone, and the like may be mentioned preferably.

The content of solvent relative to the entire amount of organic film forming composition is preferably 70 mass % to 99.9 mass %, more preferably 90 mass % to 99.5 mass %. The solvent and the solid components are mixed so that the content of solvent relative to the total amount of organic film forming composition is in the above-described predetermined ratio, and are subjected to the coating film forming step below as the organic film forming composition.

### (2) Coating Film Forming Step

Next, the above-obtained organic film forming composition is applied on one main surface of the anode or the cathode in a planar film shape, which is formed in advance by an ordinary method, by a common method such as ink jetting, spin coating, doctor blading, spray coating, die coating, bar coating, roll coating, or the like. The electrode on which the coating film is formed may either be the anode or the cathode. When pattern formation is necessary, a pattern is formed by a method such as screen printing, gravure printing, flexographic printing, or the like. Note that film formation is performed so that the thickness of the coating film becomes the above preferred film thickness as a final film thickness after a heat treatment below.

Here, when the coating film is formed on the anode for example, the coating film forming surface may be one main surface of the anode 1 as in the photoelectric conversion element 10B illustrated in FIG. 2. Further, when a functional layer similar to the hole transport layer 5 is provided on the anode 1 as in the photoelectric conversion element 10A illustrated in FIG. 1, the coating film of the organic film forming composition is formed on a main surface of this functional layer. Further similarly, when the coating film is formed on the cathode, the coating film forming surface is one main surface of the cathode 2 as in the photoelectric conversion element 10B illustrated in FIG. 2 or a main surface of a functional layer similar to the electron transport layer 6 formed on the cathode 2 as in the photoelectric conversion element 10A illustrated in FIG. 1.

A surface state of the functional layer similar to the hole transport layer or the electron transport layer can be adjusted easily to an advantageous state for film formation and orientation, as compared to electrodes such as an anode and a cathode. In the embodiments of the present invention, for example, when the hole transport layer and/or the electron transport layer is used as the functional layer, it is preferred to select a hole transport layer and/or an electron transport layer on which a hydrophilic surface can be obtained.

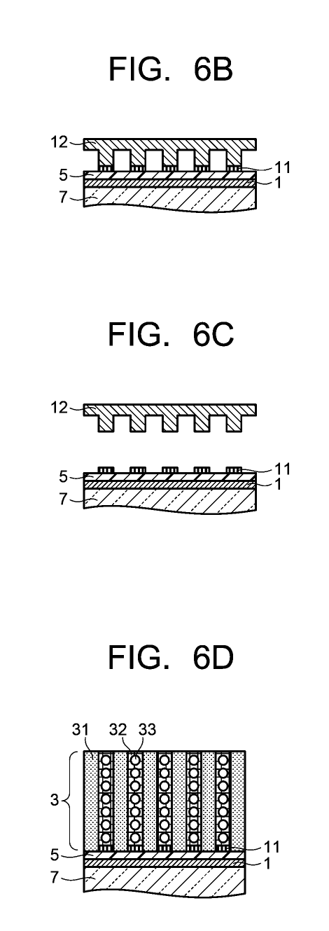

Moreover, preferably, only a region where a phase containing electron acceptors is formed is selectively treated to be hydrophobic on the hydrophilic hole transport layer and/or electron transport layer, and then the coating film formation is performed. Hereinafter, the hydrophilic hole transport layer will be described as an example, but the same procedure can be performed on the hydrophilic electron transport layer. For example, after a hydrophobic film 11 is formed partially on a surface of the hole transport layer 5 by nanoimprinting which is summarized in FIGS. 6A to 6D, the coating film formation may be performed using the organic film forming composition similarly to above.

The hydrophobic film pattern to be formed by the nanoimprinting is, specifically, selected from the lamellar structure illustrated in FIG. 3 or the cylinder structure illustrated in FIGS. 4A to 4C, which is assumed by the type of conjugated block polymer to be used. The region where the hydrophobic film 11 is formed is a region where a phase containing electron acceptors is to be formed.

The hydrophobic film 11 is constituted of, for example, an alkoxy silane coupling agent, fluorine-containing silane coupling agent, fluororesin, silicone resin, or the like. Such a hydrophobic film 11 is formed on front ends of a mold 12, the front ends being formed in the above pattern (FIG. 6A). Then, the mold 12 is mounted on the hole transport layer 5, and the mold 12 is pressed with a predetermined pressure (FIG. 6B), thereby transferring the hydrophobic film 11 on the front ends of the mold 12 onto the hole transport layer 5 (FIG. 6C).

As the mold 12, for example, one formed from a material such as metal, metal oxide, ceramics, semiconductor, or thermosetting polymer can be used, but the material is not limited in particular as long as it can form the pattern of the hydrophobic film 11 on the hole transport layer 5.

On an upper surface of the hydrophilic hole transport layer 5 on which the pattern of the hydrophobic film 11 is formed in this manner, the organic film forming composition is applied, and it is subjected to the following heat treatment step. Thus, the organic film 3 can be obtained on which, for example, the two phases of the phase 31 constituted of the electron-donating block and the phase 32 having the electron acceptors 33 are formed alternately and regularly, standing upright on the hole transport layer 5 (FIG. 6D).

### (3) Heat Treatment Step

The coating film formed above is then subjected to drying as necessary for removing the solvent. The drying can be performed by, for example, retaining at temperatures of 50° C. to 120° C. for 5 minutes to 60 minutes. By heating the coating film subjected to the drying as necessary, the liquid-crystalline conjugated block polymer in the coating film is oriented in a certain direction so that the molecular surface is in parallel with the main surface of the anode or the hole transport layer. The heating temperature is in a temperature range in which the liquid-crystalline conjugated block polymer used is in a liquid-crystalline state (from Tm to Ti). Specifically, it is preferred to perform the heat treatment in the temperature range of [Tm+10° C.] to [Ti−10° C.] of the liquid-crystalline conjugated block polymer used. The heat treatment time is preferably 3 minutes to 60 minutes.

When the drying is not performed, the drying, that is, solvent removal is performed simultaneously as the heat treatment for orienting the conjugated block polymer. Moreover, when the conjugated block polymer having a cross-linking group as the conjugated block polymer is used, a cross-linking treatment is performed, such as heating, light irradiation, or the like according to cross-linking conditions of the cross-linking group after the heat treatment and cooling. Thus, the organic film 3 is formed on the main surface of the anode 1 or the hole transport layer 5 or the main surface of the cathode 2 or the electron transport layer 6.

### (4) Electrode Forming Step

Next, by forming the electrode which is not formed in the step (2) by an ordinary method on the above-obtained organic film, the photoelectric conversion element according to the embodiments of the present invention can be obtained. That is, when the anode is formed in the step (2), after the electron transport layer is formed as necessary on the organic film, the cathode is formed thereon in this step (4). When the cathode is formed in the step (2), after the hole transport layer is formed as necessary on the organic film, the anode is formed thereon in this step (4).

Here, when the (3) heat treatment step is performed after the (4) electrode forming step is performed, the drying for removing the solvent on the coating film formed in the (2) coating film forming step is normally performed before the (4) electrode forming step. Alternatively, for example, when formation of electrode is performed by vacuum deposition, solvent removal is performed in a vacuum deposition apparatus before the electrode is formed, and thus it is not necessary to provide a drying treatment in particular.

In this manner, by performing film formation combining electron donors and electron acceptors as necessary using the liquid-crystalline conjugated block polymer, the organic film 3 functioning as a photoelectric conversion layer on the photoelectric conversion element 10A, 10B self-organizes and is formed as a film having the phase-separated structure in which the electron donor phases and the electron acceptor phases stand upright and are alternately and regularly arrayed in a direction orthogonal to the main surfaces of the electrodes.

By having the phase-separated structure in which the electron donor phases and the electron acceptor phases are alternately and regularly arrayed as described above, the areas of interfaces between these phases increase, thereby improving charge separation efficiency. Further, such a phase-separated structure is formed using the liquid-crystalline conjugated block polymer by self-organization by its orientation. The widths of the electron donor phases and the electron acceptor phases standing upright with respect to the electrode surfaces on the organic film can be adjusted easily by controlling the chain lengths of block units constituting the conjugated block polymer. Thus, the excellent charge separation efficiency can be obtained with high reproducibility. Moreover, by exhibiting a phase structure with high regularity, electron mobility close to that of crystal can be attained. Further, an even orientation can be obtained, which allows suppressing occurrence of what is called a trap site, which causes trapping of charges, and suppressing decrease in charge transport efficiency.

The photoelectric conversion element 10A illustrated in FIG. 1 and the photoelectric conversion element 10B illustrated in FIG. 2 have the anode 1 and the cathode 2 opposing each other to sandwich the organic film 3 directly or via functional layers. Either one of the electrodes is a transparent electrode transparent to light which is photoelectrically converted and is structured as a mechanism in which light is irradiated from the transparent electrode side. Normally, the anode 1 is formed as the transparent electrode. Further, in this case, the cathode 2 is formed as a metal thin film. These electrodes are formed as thin films, and thus normally they have substrates on surfaces not opposing each other, that is, outside surfaces. The substrate provided on the transparent electrode side is a transparent substrate.

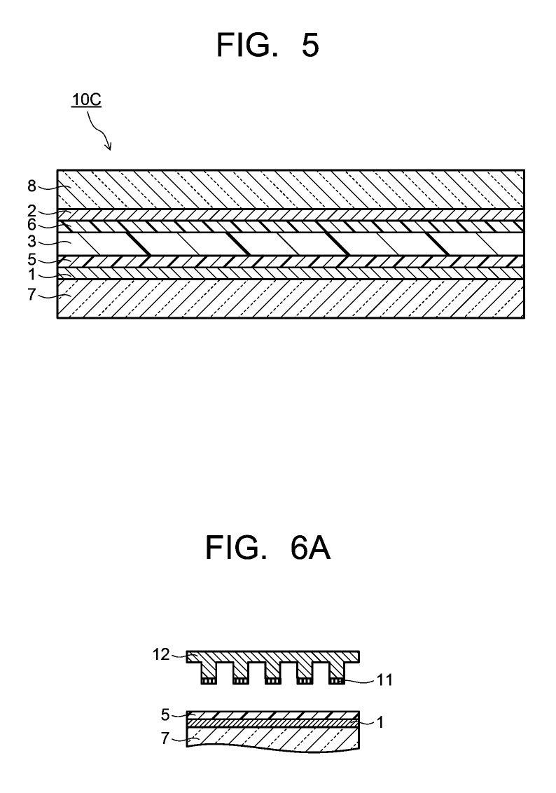

Also in the photoelectric conversion element according to the embodiments of the present invention, it is preferred to provide such substrates on outsides of both the electrodes. FIG. 5 illustrates a cross section of another example conceivable as an embodiment of the photoelectric conversion element of the present invention, which has substrates on outsides of both the electrodes in this manner on the photoelectric conversion element 10A illustrated in FIG. 1. Respective components of a photoelectric conversion element 10C illustrated in FIG. 5 will be described below.

The photoelectric conversion element 10C whose cross section is illustrated in FIG. 5 is structured by layering a transparent electrode 1 as an anode, a hole transport layer 5, an organic film 3 having a photoelectric conversion function, an electron transport layer 6, a metal electrode 2 as a cathode, and a substrate 8 in this order on a planar transparent substrate 7.

The organic film 3 having a photoelectric conversion function can be identical to the organic film 3 used in the photoelectric conversion element 10A, 10B. Preferred modes are also the same. Note that the transparent electrode 1 as an anode, the hole transport layer 5, the electron transport layer 6, and the metal electrode 2 as a cathode, which will be described below, can be applied as they are to the photoelectric conversion element 10A, 10B.

Specifically, the organic film 3 has phases composed of block units A and phases composed of block units B which are arrayed alternately so as to stand upright with respect to the electrode surfaces. In order to function as a photoelectric conversion layer, the organic film 3 is structured such that the block units A of the conjugated diblock copolymer are electron-donating blocks, the block units B are electron acceptor compatible blocks, and moreover, electron acceptors are dispersed in phases formed of the electron acceptor compatible blocks.

As the transparent substrate 7, it is possible to use a glass substrate or a bendable transparent resin substrate which has been conventionally used in photoelectric conversion element applications and which sufficiently transmits light to be photoelectrically converted, for example, sunlight. As the bendable transparent resin substrate, one which excels in chemical stability, mechanical strength, and transparency is preferred, and examples include polyethylene terephthalate (PET), polyethylene naphthalate (PEN), polyimide, polyether ether ketone (PEEK), polyethersulfone (PES), polyetherimide (PEI), and the like.

As the thickness of the transparent substrate 7, in the case of the glass substrate, 0.3 mm to 1.0 mm is preferred for having both workability and light transmission property. In the case of the transparent resin substrate, the thickness is preferably 50 μm to 300 μm. When the thickness of the transparent resin substrate is less than 50 μm, the amounts of oxygen and moisture penetrating the substrate increase, and the organic film 3 may be damaged. On the other hand, when the thickness of the transparent resin substrate exceeds 300 μm, the light transmission property may become insufficient.

The transparent electrode (anode) 1 is provided in a thin film form on an upper surface of the transparent substrate 7. As a transparent electrode substance constituting the transparent electrode (anode) 1, a transparent oxide such as an indium tin oxide (ITO), a conductive high polymer, a graphene thin film, a grapheme oxide thin film, an organic transparent electrode such as a carbon nanotube thin film, an organic and inorganic bonding transparent electrode such as a carbon nanotube thin film to which metal is bonded, or the like can be used. The thickness of the transparent electrode 1 is not particularly limited, but is preferred to be 1 nm to 200 nm.

Sheet resistance of the transparent substrate 7 on which the transparent electrode 1 is formed is preferably 5Ω/□ to 100Ω/□. When the sheet resistance is less than 5Ω/□, coloring occurs in the transparent electrode 1, and a light absorption amount of the organic film 3 may decrease. On the other hand, when the sheet resistance exceeds 100Ω/□, the sheet resistance is too large, and power generation effects may not be obtained.

Formation of the transparent electrode 1 can be performed by, for example, sputtering or applying and drying the above-described transparent electrode substance. When it is formed by applying and drying, for example, one dissolved in a solvent such as water or methanol is applied by spin coating or the like on the transparent substrate 7 and dried, so as to form the electrode. The drying can be performed by, for example, retaining at temperatures of 100° C. to 200° C. for 1 minute to 60 minutes.

The hole transport layer 5 is provided in a thin film form between the transparent electrode 1 and the organic film 3. As a hole transport substance constituting the hole transport layer 5, examples include poly(3,4-ethylene dioxythiophene)-polystyrene sulfonate (PEDOT:PSS), polyaniline, copper phthalocyanine (CuPC), polythiophenylene vinylene, polyvinyl carbazole, polyparaphenylene vinylene, polymethylphenyl silane, and the like. Among them, PEDOT:PSS is preferred by which a hydrophilic surface can be obtained in addition to the above-described function. Note that only one of them may be used, or two or more of them may be used in combination.

A method of forming a film of the hole transport substance on an upper surface of the transparent electrode 1 to form the hole transport layer 5 is such that, for example, a coating liquid containing the above-described hole transport substance and solvent is applied by, for example, the same method as that for applying the organic film forming composition, such as spin coating, and this liquid is dried (solvent removal) to form the layer. The drying can be performed by, for example, retaining at temperatures of 120° C. to 250° C. for 5 minutes to 60 minutes.

A thickness of the hole transport layer 5 is preferably 30 nm to 100 nm. When the thickness of the hole transport layer 5 is less than 30 nm, functions such as collecting holes, hindering transition of electrons to the anode, and preventing short circuit may not be obtained sufficiently. On the other hand, when the thickness of the hole transport layer 5 exceeds 100 nm, the sheet resistance may become excessively high by the influence of electrical resistance of the hole transport layer 5 itself, or the amount of light absorption in the organic film 3 may decrease by light absorption of the hole transport layer 5 itself.

The organic film 3 is formed as described above on the hole transport layer 5, and the electron transport layer 6 is formed thereon. The electron transport layer 6 is provided in a thin film form in a region between the organic film 3 and the metal electrode 2, and has functions such as hindering transition of holes to the cathode, preventing short circuit, and collecting electrons as described above.

As an electron transport substance forming the electron transport layer 6, examples include a lithium fluoride (LiF), calcium, lithium, titanium oxide, and the like. Among them, LiF and titanium oxide can be used preferably.

A method for forming the electron transport layer 6 is such that, for example, the electron transport substance is deposited on an upper surface of the organic film 3 by a method such as vacuum deposition or sputtering, or the electron transport substance is dissolved in a solvent and is applied by a method such as spin coating or doctor blading and is dried, so as to form the layer. Among them, the vacuum deposition is used preferably in view of uniformly forming a film of the electron transport substance on the organic film 3 surface. Note that deposition of the electron transport substance and application of the electron transport substance dissolved in the solvent can also be performed using a shadow mask.

A thickness of the electron transport layer 6 is preferably 0.1 nm to 5 nm. When the thickness of the electron transport layer 6 is less than 0.1 nm, control of the film thickness is difficult, and it is possible that stable characteristics cannot be obtained. On the other hand, when the thickness of the electron transport layer 6 is more than 5 nm, the sheet resistance becomes excessively high, and an electric current value may decrease.

The metal electrode 2 functioning as the cathode is formed on an upper portion of the electron transport layer 6. As a metal electrode substance forming the metal electrode (cathode) 2, there may be mentioned calcium, lithium, aluminum, alloy of lithium fluoride and lithium, gold, conductive polymer, a mixture thereof, or the like. Among them, aluminum and gold can be used preferably.

As a method for forming the metal electrode 2, for example, it can be formed by depositing the metal electrode substance on an upper surface of the electron transport layer 6 by, for example, vacuum deposition, or the like. Note that deposition of the metal electrode substance can also be performed by using a shadow mask.

A thickness of the metal electrode 2 is preferably 50 nm to 300 nm. When the thickness of the metal electrode 2 is less than 50 nm, the organic film 3 may be damaged by moisture, oxygen, or the like, and the sheet resistance may become excessively high. On the other hand, when the thickness of the metal electrode 2 exceeds 300 nm, the time needed for forming the metal electrode 2 becomes too long, or costs may increase.

The substrate 8 is disposed on an upper surface of the metal electrode 2. The substrate 8 can be disposed on the upper surface of the metal electrode 2 by adhesion using, for example, an epoxy resin, acrylic resin, or the like. As the substrate 8, it is preferred to use one of the same size and material as the transparent substrate 7, but it need not necessarily be transparent like the transparent substrate 7.

Thus, the photoelectric conversion elements 10A, 10B, and 10C have been described as examples of embodiments of the photoelectric conversion element of the present invention, but the structure of the photoelectric conversion element of the present invention is not limited to them, and can be changed appropriately according to required characteristics and the like to the extent that it is not contrary to the spirit of the present invention.

Further, the cases where the photoelectric conversion elements 10A and 10B are produced have been described as examples of embodiments of the manufacturing method of the photoelectric conversion element of the present invention, but the steps and the order thereof in the manufacturing method of the photoelectric conversion element of the present invention are not limited thereto, and may be changed appropriately according to required characteristics and the like of the photoelectric conversion element to the extent that it is not contrary to the spirit of the present invention.

According to the present invention, it is possible to provide a photoelectric conversion element with high photoelectric conversion efficiency, whose light absorption efficiency, charge separation efficiency, and charge transport efficiency are all at high level. By the manufacturing method of the present invention, the photoelectric conversion element of the present invention can be produced efficiently. Such a photoelectric conversion element according to the present invention can be used preferably as, for example, an organic thin film solar cell. Specifically, by using the photoelectric conversion element as an organic thin film solar cell and sealing it with a resin or the like, an organic thin film solar cell module with high photoelectric conversion efficiency can be obtained.

### EXAMPLES

Hereinafter, examples of the present invention will be described, but the present invention is not limited to these examples. Examples 1 to 4 are working examples, and Examples 5 to 7 are comparative examples.

### Example 1

In the following procedure, a liquid-crystalline conjugated block polymer is synthesized, this block polymer is used to produce a photoelectric conversion element 1 in which a transparent substrate, an anode, a hole transport layer, an organic film, and a cathode are layered in this order, and performances thereof are evaluated.

(Synthesizing the Liquid-Crystalline Conjugated Block Polymer and Preparing The Organic Film Forming Composition)

As the liquid-crystalline conjugated block polymer, a conjugated diblock copolymer (BP1) represented by following formula (BP1) is synthesized as follows. In the conjugated diblock copolymer (BP1), a repeating portion of “n” number of 3-hexylthiophene units (hereinafter also referred to as a “P3HT block”) is crystalline and functions as an electron-donating block. Being crystalline was determined by that a homopolymer (homopolymer-C) of the 3-hexylthiophene illustrated in Examples 6, 7 below is crystalline.

On the other hand, a repeating portion of “m” number of 9,9-dioctyl-9H-fluorene units (hereinafter also referred to as a “PF8 block”) is liquid crystalline and functions as an electron acceptor compatible block. Being liquid crystalline was determined by that a homopolymer (homopolymer-D) of the 9,9-dioctyl-9H-fluorene illustrated in Examples 6, 7 below is liquid-crystalline.

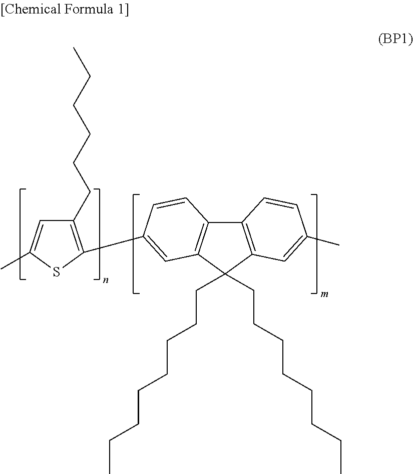

(i) Preparing a Reaction Solution

An eggplant flask was decompressed and dried while being heated with a heat gun, and was substituted with argon. To this, 2-bromo,5-iodine-3-hexylthiophene 1.0 g (2.7 mmol) was added, and it was substituted again with argon. Thereafter, an anhydrous THF 5 ml was added using a dried syringe in an N₂ flow, and it was cooled to 0° C. In an N₂ flow, 1.35 mL (2.7 mmol) of an isopropyl magnesium chloride-THF solution (2.0 mol/L) was added using a dried syringe, and it was agitated for one hour at 0° C., thereby obtaining a reaction solution A containing a (5-bromo-3-hexylthiophene-2-yl) magnesium chloride.

Next, another eggplant flask was decompressed and dried while being heated using a heat gun, and is substituted with nitrogen. To this, 2,7-dibromo-9,9-dioctyl-9H-fluorene 0.65 g (1.1 mmol) was added, and it was substituted again with argon. Thereafter, an anhydrous THF (3 ml) was added using a dried syringe in an N₂ flow. After the 2,7-dibromo-9,9-dioctyl-9H-fluorene was dissolved completely, 0.84 mL (1.1 mmol) of a THF solution of isopropyl magnesium chloride and lithium chloride complex (1.3 mol/L) was added using a dried syringe, and then it was agitated for six hours at 40° C., thereby obtaining a solution containing a (7-bromo-9,9-dioctyl-9H-fluorene-2-yl) magnesium chloride. To the obtained solution, an anhydrous THF 20 ml was added using a dried syringe to dilute it, thereby obtaining a reaction solution B.

(ii) Polymerization

To the above-obtained reaction solution B, 0.005 g of [1,2-bis(diphenylphosphino)propane]nickel(II)dichloride(Ni(dppp)Cl2) was added as catalyst, and it was agitated for 20 minutes to carry out polymerization of first stage. By this polymerization, a PF8 block part in a conjugated diblock copolymer (BP1) was synthesized. Thereafter, the reaction solution A was added to the solution which completed the polymerization of first stage, and let them react for 20 minutes to carry out polymerization of second stage. By this polymerization, a conjugated diblock copolymer (BP1) having a structure in which the P3HT block is bonded to the PF8 block was obtained.

Note that the polymerization of first stage and the polymerization of second stage were performed in succession, and after the polymerization reaction of second stage was finished, a 2M hydrochloric acid aqueous solution was added to the reaction solution to stop the reaction. The obtained reaction solution was dripped into a 200 mL methanol, and a crude polymerization product was collected by filtering. The crude polymerization product was washed by a Soxhlet extraction method (solvent: hexane and methanol), and the remaining polymerization product was dissolved with a chloroform. The obtained chloroform solution was dripped into a methanol with a mass of 20 times, and it was agitated to cause precipitation of solids. The obtained solids were filtered and vacuum dried overnight at 40° C., thereby obtaining a copolymer A (conjugated diblock copolymer (BP1)).

Confirmation of that the copolymer A is the conjugated diblock copolymer (BP1) and measurement of structure and material properties were performed as follows.

### (a) Properties

The obtained copolymer A exhibited a dark purple color, and was soluble in chloroform, toluene, and chlorobenzene.

### (b) Molecular Weight and Molecular Weight Distribution

A molecular weight and a molecular weight distribution of the obtained copolymer A were measured by GPC (Gel Permeation Chromatography). As a result, regarding a precursor of the copolymer A obtained in the polymerization of first stage, a number average molecular weight (Mn) and a molecular weight distribution indicated by mass average molecular weight/number average molecular weight (Mw/Mn) were 6,500 and 1.3, respectively. Thus, the degree of polymerization “m” of the 9,9-dioctyl-9H-fluorene unit is calculated as 16.7 in average value, and a length of the PF8 block is further calculated as 13.5 nm.

In the copolymer A obtained in the polymerization of second stage, the number average molecular weight (Mn) and the molecular weight distribution (Mw/Mn) were 18,000 and 1.5, respectively. Thus, the degree of polymerization “n” of the 3-hexylthiophene unit is calculated as 68.5 in average value, and a length of the P3HT block is further calculated as 24.7 nm.

Note that a molecular weight distribution curve of the copolymer A shifts to a high molecular weight side in a single peak, from which it was seen that a block-type conjugated diblock copolymer (BP1) was obtained in the polymerization reaction in two stages.

### (c) NMR Measurement

A composition of the obtained copolymer A was calculated by 1H-NMR. A ratio (mole %) of the 9,9-dioctyl-9H-fluorene unit and the 3-hexylthiophene unit was 20%:80%.

### (d) Confirmation of Liquid Crystallinity

The obtained copolymer A was confirmed to have liquid crystallinity by DSC (differential scanning calorimetry) and observation by a polarizing microscope as follows. With respect to the copolymer A, a phase transition point (Tm) when changing from a solid phase to a liquid-crystalline phase and a phase transition point (Ti) when changing from the liquid-crystalline phase to a liquid phase were measured using DSC. Tm was 150° C. and Ti was 220° C., and it was confirmed that the copolymer A is in a liquid-crystalline state in the temperature range of 150° C. to 220° C. Further, a texture indicating a liquid phase was observed with the polarization microscope.

10 mg of the obtained copolymer A, namely, conjugated diblock copolymer (BP1) and 10 mg of a fullerene derivative (PC60BM) functioning as electron acceptor were dissolved in 1 ml of a chlorobenzene, and it was filtered with a filter of 0.20 μm size, thereby obtaining an organic film forming composition 1.

(Production of the Photoelectric Conversion Element)

A transparent substrate with an ITO transparent electrode having a thickness of 140 nm (sheet resistance of the substrate with the ITO electrode: 10Ω/□, the transparent substrate being a non-alkali glass (manufactured by EHC), 15 mm×15 mm, 0.7 mm film thickness) was washed for 30 minutes in each of an alkali detergent, ultrapure water, acetone, and i-propanol in this order using an ultrasonic washing machine, thereafter dried by nitrogen blow using a nitrogen gun, and washed for 30 minutes with ultraviolet ozone.

On this ITO transparent electrode, a poly(3,4-ethylene dioxythiophene)-polystyrene sulfonate aqueous solution (manufactured by H.C. starck; product name “Baytoron A1 4083”) was applied by spin coating after filtration using a filter of 0.45 μm size, and was dried in the atmosphere for five minutes at 150° C., forming a hole transport layer having a film thickness of 40 nm. Note that the film thickness was measured with a contact-type thickness meter DEKTAK. Hereinafter, measurement of a film thickness of each layer was performed similarly. The above-obtained organic film forming composition 1 was applied on the hole transport layer by spin coating, thereby forming an organic film.

Next, a shadow mask was placed on the organic film, and aluminum was deposited on the organic film in a state of being decompressed to 10⁻³ Pa or lower in a vacuum deposition apparatus, thereby forming an aluminum electrode with a thickness of 70 nm. Moreover, it was heat treated at 160° C. for 10 minutes. Thus, a photoelectric conversion element 1 (with an effective light receiving area of 4 mm²) was produced, which was assumed to have an organic film having a phase-separated structure in which the conjugated diblock copolymer (BP1) constituting the organic film is self-organized and regularly arrayed by its liquid crystallinity. The film thickness of the organic film in the photoelectric conversion element 1 was 120 nm.

Note that regarding the film thickness of the organic film in the photoelectric conversion element 1, a sample for film thickness measurement was obtained similarly to above except that the hole transport layer is not formed on the ITO transparent electrode and the aluminum electrode is not formed on the organic film in the production of the photoelectric conversion element 1, and a film thickness of the sample measured using the contact-type thickness meter DEKTAK was used as it is. Hereinafter, in all the examples, regarding the film thickness of the organic film, a film thickness obtained by the same measurement method as above was used.

(Evaluation)

The above-obtained photoelectric conversion element 1 was placed in a testing apparatus, and simulated sunlight of 100 mW/cm² was irradiated from a transparent substrate side of the photoelectric conversion element 1 using a solar simulator (PEC-L15 manufactured by Peccell Technologies). The photoelectric conversion characteristic of the photoelectric conversion element 1 at this time was measured as follows. As a result, a value of fill factor (FF) was 0.66.

(Measurement Method)

Regarding the photoelectric conversion element 1, during the light irradiation, an output voltage when terminals were made open was measured as an open-circuit voltage (V_{OC}), and a current when it was short-circuited was measured as a short-circuit current (I_{SC}). Further, a value of dividing I_{SC} by an effective light receiving area “S” (4 mm² in the photoelectric conversion element 1) was calculated as a short-circuit current density (J_{SC}). The operating point which gives a maximum output voltage was obtained as a maximum power point (Pₘₐₓ), and a value of dividing an actual maximum power (Jₘₐₓ×Vₘₐₓ) at Pₘₐₓ by an ideal maximum power (J_{SC}×V_{OC}) was evaluated as the fill factor (FF).

### (Formula for Obtaining FF)

FF=(Jₘₐₓ×Vₘₐₓ)/(J_{SC}×V_{OC})

Note that for increasing the actual maximum power, it is necessary to make J_{SC}, V_{OC}, and FF high. In the photoelectric conversion element of a solar cell or the like utilizing an organic thin film, it is considered that FF becomes high when charge transport efficiency is high, contributing to increasing the actual maximum power.

### Example 2 to Example 4

As Example 2, a photoelectric conversion element 2 was produced similarly to Example 1 except that the film thickness of the organic film in Example 1 was changed to 200 nm. Similarly, a photoelectric conversion element 3 in which the film thickness of the organic film was changed to 300 nm was produced as Example 3, and a photoelectric conversion element 4 in which the film thickness of the organic film was changed to 600 nm was produced as Example 4. Regarding the obtained photoelectric conversion elements 2 to 4, the photoelectric conversion characteristic was evaluated in the same way as above. Values of fill factors (FF) were 0.60, 0.58, and 0.51, respectively.

An organic film having a film thickness of 200 nm was formed and an aluminum electrode was formed similarly to Example 2. The heat treatment temperatures thereafter were changed to 170° C. and 180° C., respectively, and a heat treatment was performed. Values of fill factors (FF) in both of these two samples were also 0.60.

### Example 5

The reaction solution A and reaction solution B prepared similarly to Example 1 were used to synthesize a random copolymer in which 3-hexylthiophene units and 9,9-dioctyl-9H-fluorene units are bonded in an arbitrary order. First, to a solution obtained by adding the reaction solution B to the reaction solution A, 0.005 g of Ni(dppp)Cl2 was added, and it was agitated for two hours. After this agitation for two hours, a 2M hydrochloric acid aqueous solution was added to stop the reaction. The obtained reaction solution was dripped into a 200 mL methanol, and a crude polymerization product was collected by filtering. The crude polymerization product was washed by a Soxhlet extraction method (solvent: hexane and methanol), and the remaining polymerization product was dissolved with a chloroform. The obtained chloroform solution was dripped into a methanol with a mass of 20 times, and it was agitated to cause precipitation of solids. The obtained solids were filtered and vacuum dried overnight at 40° C., thereby obtaining a copolymer B (random copolymer) of 9,9-dioctyl-9H-fluorene and 3-hexylthiophene.

Confirmation of that the copolymer B is a random copolymer and measurement of structure and material properties were performed as follows. The obtained copolymer B exhibited a dark purple color, and was soluble in chloroform, toluene, and chlorobenzene. A molecular weight and a molecular weight distribution of the obtained copolymer B were measured similarly to the copolymer A. As a result, the number average molecular weight (Mn) and the molecular weight distribution (Mw/Mn) were 23,000 and 1.45, respectively. Further, a molecular weight distribution curve of the copolymer B is in a single peak state, and it was confirmed to be a random copolymer. A composition of the obtained copolymer B was calculated by 1H-NMR similarly to the copolymer A, and then a ratio (mole %) of the 9,9-dioctyl-9H-fluorene unit and the 3-hexylthiophene unit was 23%:77%. Further, regarding the copolymer B, presence of liquid crystallinity was attempted to confirm using the DSC and the polarizing microscope similarly to the copolymer A, but the liquid crystallinity was not confirmed and it was confirmed to be amorphous.

A photoelectric conversion element 5 in which the organic film has a film thickness of 120 nm was produced similarly to Example 1 except that the above-obtained random copolymer B of 9,9-dioctyl-9H-fluorene and 3-hexylthiophene was used instead of the conjugated diblock copolymer (BP1). Regarding the obtained photoelectric conversion element 5, the photoelectric conversion characteristic was evaluated similarly to Example 1. A value of fill factor (FF) was 0.25.

### Examples 6, 7

Poly(3-hexylthiophene) (Manufactured by Merck) was prepared as a homopolymer C and a homopolymer D of 9,9-dioctyl-9H-fluorene was synthesized as follows, and a mixture of them was used for forming the organic film to produce a photoelectric conversion element. In the homopolymer C, the number average molecular weight (Mn) and the molecular weight distribution (Mw/Mn) were 28,000 and 1.3, respectively. Further, regarding the homopolymer C, presence of liquid crystallinity was attempted to confirm using the DSC and the polarizing microscope similarly to the copolymer A, but the liquid crystallinity was not confirmed and it was confirmed to be crystalline.

Further, an eggplant flask was decompressed and dried while being heated with a heat gun, and was substituted with nitrogen. To this, 1.3 g (2.2 mmol) of 2,7-dibromo-9,9-dioctyl-9H-fluorene was added, and it was substituted again with argon. Thereafter, an anhydrous THF (5 ml) was added using a dried syringe in an N₂ flow. After the 2,7-dibromo-9,9-dioctyl-9H-fluorene was dissolved completely, 1.68 mL (2.2 mmol) of a THF solution of isopropyl magnesium chloride and lithium chloride complex (1.3 mol/L) was added using a dried syringe, and then it was agitated for six hours at 40° C., thereby obtaining a reaction solution containing a (7-bromo-9,9-dioctyl-9H-fluorene-2-yl) magnesium chloride. To the reaction solution, 0.010 g of Ni(dppp)Cl2 was added, and it was agitated for 120 minutes to carry out polymerization.

After this agitation for 120 minutes, a 2M hydrochloric acid aqueous solution was added to stop the reaction. Similarly to above, the polymer product was refined and collected from the reaction solution, thereby obtaining a homopolymer D of 9,9-dioctyl-9H-fluorene. The obtained homopolymer D was a light-yellow solid, and the number average molecular weight (Mn) and molecular weight distribution (Mw/Mn) therein were 14,000 and 1.8, respectively. Further, regarding the homopolymer D, presence of liquid crystallinity was confirmed using the DSC and the polarizing microscope similarly to the copolymer A, and a liquid-crystalline state was confirmed between 140° C. (Tm) and 210° C. (Ti).

A photoelectric conversion element 6 in which the organic film has a film thickness of 110 nm and a photoelectric conversion element 7 in which the organic film has a film thickness of 182 nm were produced similarly to Example 1 except that a mixture containing the above-obtained homopolymer D of 9,9-dioctyl-9H-fluorene and homopolymer C of 3-hexylthiophene in a mass ratio of 1:1 is used instead of the conjugated diblock copolymer (BP1). Regarding the obtained photoelectric conversion elements 6, 7, the photoelectric conversion characteristic was evaluated similarly to Example 1. Values of fill factors (FF) were 0.42 and 0.19, respectively. Results are summarized in Table 1.

TABLE 1

| | | Photo- | Film | |
|---|---|---|---|---|
| | | electric | thick- | Fill |
| | Polymer material used | conversion | ness | factor |
| | for organic film formation | element | (nm) | (FF) |
| Example 1 | Conjugated diblock copolymer | 1 | 120 | 0.66 |
| | (BP1) | | | |
| Example 2 | Conjugated diblock copolymer | 2 | 200 | 0.60 |
| | (BP1) | | | |
| Example 3 | Conjugated diblock copolymer | 3 | 300 | 0.58 |
| | (BP1) | | | |
| Example 4 | Conjugated diblock copolymer | 4 | 600 | 0.51 |
| | (BP1) | | | |
| Example 5 | Random copolymer (copolymer B) | 5 | 120 | 0.25 |
| Example 6 | Mixture of homopolymer C and | 6 | 110 | 0.42 |
| | homopolymer D | | | |
| Example 7 | Mixture of homopolymer C and | 7 | 182 | 0.19 |
| | homopolymer D | | | |

As can be seen from Table 1, the photoelectric conversion elements of Example 1 to Example 4 having an organic film formed using the conjugated diblock copolymer (BP1) is assumed to have a structure in which the conjugated block polymer is oriented in a direction orthogonal to the opposing electrode surfaces, and phases composed of block units stand upright in the orthogonal direction, as substantially illustrated in the organic film 3 of FIG. 1. More specifically, it is assumed that the elements substantially have a structure such that, in the above-described structure, the P3HT block constitute the phases 31 as electron-donating blocks, the PF8 block constitute the phases 32 as electron acceptor compatible blocks, and moreover the fullerene derivative (PC60BM) of electron acceptor exist in a state of being incorporated in the phases 32. Thus, it can be said that there is provided a photoelectric conversion element in which the value of fill factor (FF) is maintained high without being affected by the film thickness, that is, a photoelectric conversion element with high photoelectric conversion efficiency, whose light absorption efficiency, charge separation efficiency, and charge transport efficiency are all at high level.

(Liquid-Crystalline Conjugated Block Polymer (2))

As a liquid-crystalline conjugated block polymer, a conjugated diblock copolymer (BP2) represented by following formula (BP2) is synthesized.

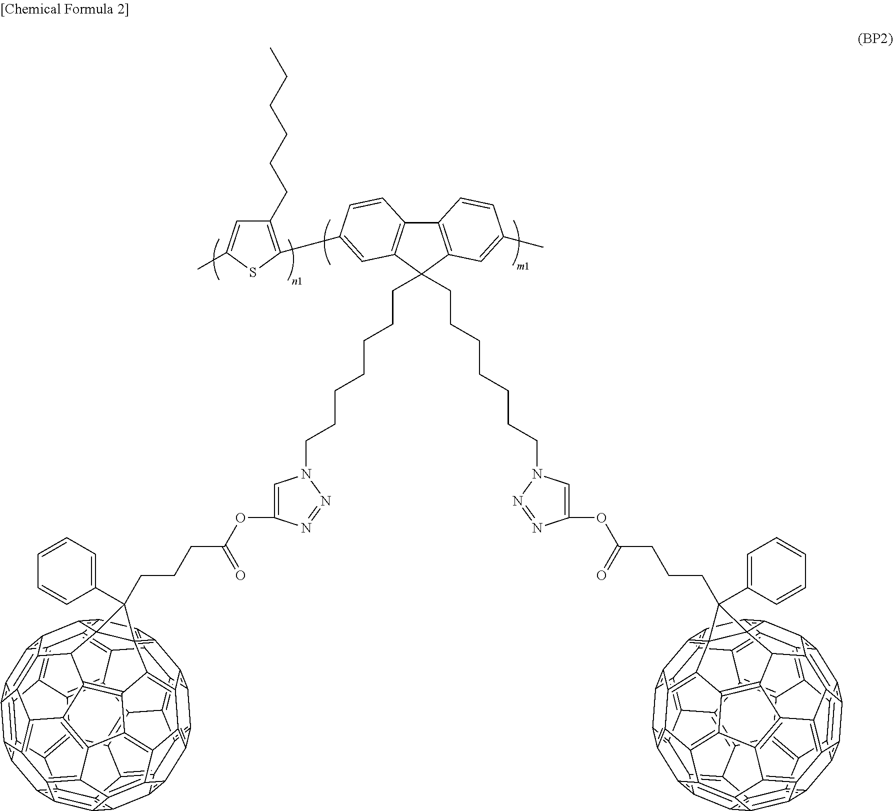

A repeating portion of “n1” number of 3-hexylthiophene units is crystalline and functions as an electron-donating block. Further, a repeating portion of “m1” number of fluorene units to which side chains having a fullerene structure are introduced is liquid crystalline and functions as an electron-accepting block. In the case of this copolymer (BP2), synthesis may be carried out so that “n1” is 40 to 80 (preferably about 60) and “m1” is 2 to 8 (preferably about 5). By using this conjugated diblock copolymer (BP2), it is possible to produce the photoelectric conversion element by this copolymer alone similarly to the case where the conjugated diblock copolymer (BP1) and PC60BM are used in combination.

(Liquid-Crystalline Conjugated Block Polymer (3))

As a liquid-crystalline conjugated block polymer, a conjugated diblock copolymer (BP3) represented by following formula (BP3) is synthesized.

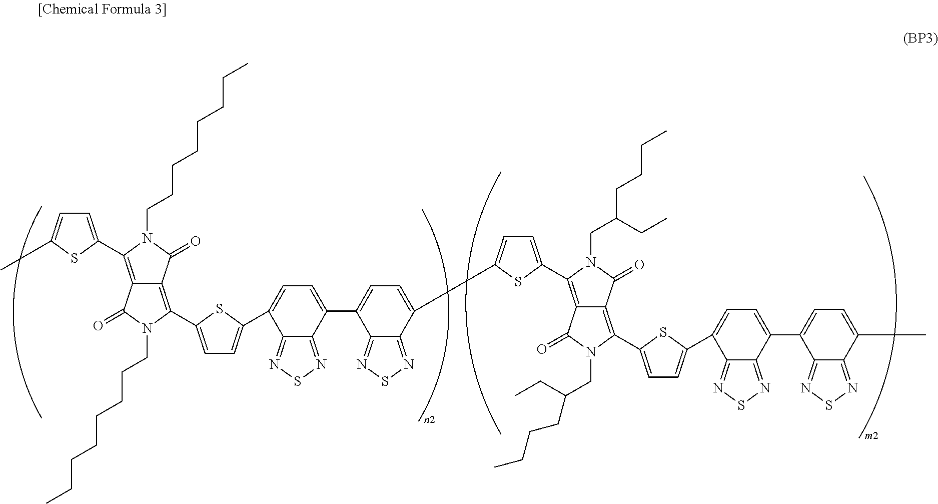

A repeating portion of “n2” number of units containing a diketopyrrolopyrrole skeleton having an n-octyl group in a side chain is crystalline and functions as an electron-accepting block. Further, a repeating portion of “m2” number of units containing a diketopyrrolopyrrole skeleton having a 2-ethylhexyl group in a side chain is liquid crystalline and functions as an electron donor compatible block. In the case of this copolymer (BP3), synthesis may be carried out so that “n2” is 4 to 8 (preferably about 6) and “m2” is 4 to 8 (preferably about 6).

When a thiophene oligomer represented by following formula (ED1) whose average degree of polymerization is 6 is further used as electron donors in combination using this conjugated diblock copolymer (BP3), a photoelectric conversion element can be produced similarly to the case where the conjugated diblock copolymer (BP1) and PC60BM are used in combination.

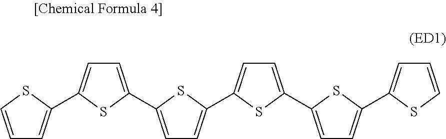 [SMILES: c1csc(-c2ccc(-c3ccc(-c4ccc(-c5ccc(-c6cccs6)s5)s4)s3)s2)c1]

A photoelectric conversion element of the present invention exhibits excellent characteristics particularly as an organic thin film solar cell. By thickening an organic film in particular, light can be absorbed sufficiently, thereby increasing power generation efficiency.

What is claimed is:

1. A photoelectric conversion element, comprising:
an anode,
a cathode opposed to said anode; and
an organic film
being disposed between the anode and the cathode, and
containing a liquid-crystalline conjugated block polymer.

2. The photoelectric conversion element according to claim 1,
wherein a film thickness of the organic film is 200 nm to 1000 nm.

3. The photoelectric conversion element according to claim 1,
wherein the organic film is a film formed by heating the liquid-crystalline conjugated block polymer at a temperature in a range in which the liquid-crystalline conjugated block polymer is in a liquid-crystalline state.

4. The photoelectric conversion element according to claim 1,
wherein the organic film is a film containing an electron acceptor and is a film containing as the liquid-crystalline conjugated block polymer a polymer constituted of a block having electron donating ability and a block compatible with the electron acceptor.

5. The photoelectric conversion element according to claim 4, wherein the electron acceptor is a chemical compound selected from a fullerene and a derivative thereof.

6. The photoelectric conversion element according to claim 1,
wherein the organic film is a film containing an electron donor and is a film containing as the liquid-crystalline conjugated block polymer a polymer constituted of a block compatible with the electron donor and a block having electron acceptability.

7. The photoelectric conversion element according to claim 1,
wherein the organic film is a film containing as the liquid-crystalline conjugated block polymer a polymer constituted of a block having electron donating ability and a block having electron acceptability.

8. The photoelectric conversion element according to claim 6,
wherein the block having electron acceptability is a block having a polymer unit which requires a fullerene structure.

9. The photoelectric conversion element according to claim 7,
wherein the block having electron acceptability is a block having a polymer unit which requires a fullerene structure.

10. The photoelectric conversion element according to claim 1,
wherein the liquid-crystalline conjugated block polymer is constituted of a liquid crystal block and a non-liquid crystal block.

11. The photoelectric conversion element according to claim 10,
wherein the non-liquid crystal block is constituted of a crystal block.

12. An organic thin film solar cell module using the photoelectric conversion element according to claim 1.

13. A method of manufacturing a photoelectric conversion element having an anode, a cathode opposed to the anode, and an organic film disposed between the anode and the cathode and containing a liquid-crystalline conjugated block polymer, comprising the steps of:
(1) preparing an organic film forming composition containing the liquid-crystalline conjugated block polymer;
(2) forming one of the anode and the cathode and forming a coating film by applying the organic film forming composition on one main surface of the electrode;
(3) heat treating the coating film within a temperature range in which the liquid-crystalline conjugated block polymer is in a liquid-crystalline state so as to obtain the organic film; and
(4) forming the other electrode which is not formed in the step (2) above the organic film.

14. The manufacturing method of the photoelectric conversion element according to claim 13, wherein the step (3) is performed after the step (4).

15. The manufacturing method of the photoelectric conversion element according to claim 13,
wherein the photoelectric conversion element is an organic thin film solar cell.
